(19) United States
(12) Patent Application Publication
(10) Pub. No.: US 2026/0231514 A1
(43) Pub. Date: Aug. 6, 2026

(54) SEMICONDUCTOR DEVICE

(71) Applicant: FUJI ELECTRIC CO., LTD., Kawasaki-shi (JP)

(72) Inventors: Takaaki SUZAWA, Matsumoto-city (JP); Motoyoshi KUBOUCHI, Matsumoto-city (JP)

(73) Assignee: FUJI ELECTRIC CO., LTD., Kawasaki-shi (JP)

(21) Appl. No.: 19/635,697

(22) Filed: Mar. 31, 2026

Related U.S. Application Data
(63) Continuation of application No. PCT/JP2025/010036, filed on Mar. 14, 2025.

(30) Foreign Application Priority Data
Mar. 15, 2024 (JP) 2024-041310

(51) Int. Cl. H10D 84/00; H10D 8/00; H10D 8/01; H10D 12/00; H10D 12/01; H10D 62/10; H10D 62/53; H10D 64/62; H10D 84/01

(52) U.S. Cl. CPC H10D 84/161; H10D 8/422; H10D 12/481; H10D 62/105; H10D 62/126; H10D 62/53; H10D 64/62; H10D 8/045; H10D 12/038; H10D 84/0109

(57) ABSTRACT

A semiconductor device having: a first semiconductor layer; a gate insulating film formed on the first semiconductor layer; a gate electrode provided on the gate insulating film; an interlayer insulating film provided on the gate electrode; a contact hole penetrating through the interlayer insulating film; a front electrode selectively formed on the interlayer insulating film and in the contact hole; a sealing film selectively formed on the front electrode and the interlayer insulating film, to thereby define, in a top view, a first region in which the sealing film is formed, and a second region and a third region in which the sealing film is not formed, the second region separating the first region and the third region; and a first barrier metal sandwiched between the front electrode and the interlayer insulating film in the second region but not in the third region.

### CROSS REFERENCE TO RELATED APPLICATIONS

This is a continuation application of International Application PCT/JP2025/010036 filed on Mar. 14, 2025 which claims priority from a Japanese Patent Application No. 2024-041310 filed on Mar. 15, 2024, the contents of which are incorporated herein by reference.

### BACKGROUND OF THE INVENTION

### 1. Field of the Invention

Embodiments of the disclosure relate to a semiconductor device.

### 2. Description of the Related Art

According to a known technique, an electrode pad and wiring are formed on an interlayer insulating film with a barrier metal film interposed therebetween, and a barrier metal removal region where the barrier metal film beneath the electrode pad is removed is formed in the barrier metal film so that the barrier metal film is left around the electrode pad (for example, refer to Japanese Laid-Open Patent Publication No. 2004-363173).

### SUMMARY OF THE INVENTION

According to an embodiment of the present disclosure, a semiconductor device includes: a semiconductor substrate having a first semiconductor layer of a first conductivity type; a gate insulating film having a first surface and a second surface opposite to each other, the second surface thereof being in contact with the first semiconductor layer; a gate electrode provided on the first surface of the gate insulating film; an interlayer insulating film provided on said gate electrode; a contact hole penetrating through the interlayer insulating film to reach a surface of the first semiconductor layer; a front electrode selectively formed on a surface of the interlayer insulating film and in the contact hole; a sealing film selectively formed on surfaces of the front electrode and the interlayer insulating film, to thereby define, in a top view of the semiconductor device, a first region that is a region in which the sealing film is formed, a second region that is a region in which the sealing film is not formed, and a third region that is another region in which the sealing film is not formed, the second region being adjacent to the first region, the third region being adjacent to the second region but not adjacent to the first region; and a first barrier metal containing a first metal, the first barrier metal being sandwiched between the front electrode and the interlayer insulating film in the second region but not in the third region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a top view of a semiconductor device according to an embodiment.

FIG. 2 is a cross-sectional view of the semiconductor device according to the embodiment, along cutting line A-A′.

FIG. 3 is a cross-sectional view depicting a structure of the semiconductor device according to the embodiment.

FIG. 4 is a top view of a first example of the semiconductor device according to the embodiment.

FIG. 5 is a top view of a second example of the semiconductor device according to the embodiment.

FIG. 6 is a top view of a third example of the semiconductor device according to the embodiment.

FIG. 7A is an enlarged top view of a region S1 of the third example of the semiconductor device according to the embodiment.

FIG. 7B is an enlarged top view of a different example of the region S1 of the third example of the semiconductor device according to the embodiment.

FIG. 7C is an enlarged top view of a different example of the region S1 of the third example of the semiconductor device according to the embodiment.

FIG. 7D is an enlarged top view of a different example of the region S1 of the third example of the semiconductor device according to the embodiment.

FIG. 7E is an enlarged top view of a different example of the region S1 of the third example of the semiconductor device according to the embodiment.

FIG. 8 is a top view of a fourth example of the semiconductor device according to the embodiment.

FIG. 9A is an enlarged top view of the region S1 of the fourth example of the semiconductor device according to the embodiment.

FIG. 9B is an enlarged top view of a different example of the region S1 of the second example of the semiconductor device according to the embodiment.

FIG. 9C is an enlarged top view of a region S2 of the fourth example of the semiconductor device according to the embodiment.

FIG. 9D is an enlarged top view of a different example of the region S1 of the second example of the semiconductor device according to the embodiment.

FIG. 10 is a top view of another structure of the semiconductor device according to the embodiment.

FIG. 11A is a cross-sectional view of another structure of the semiconductor device according to the embodiment, along cutting line A-A′.

FIG. 11B is a cross-sectional view of another structure of the semiconductor device according to the embodiment, along cutting line A-A′.

FIG. 11C is a cross-sectional view of another structure of the semiconductor device according to the embodiment, along cutting line A-A′.

FIG. 11D is a cross-sectional view of another structure of the semiconductor device according to the embodiment, along cutting line A-A′.

FIG. 11E is a cross-sectional view of another structure of the semiconductor device according to the embodiment, along cutting line A-A′.

FIG. 11F is a cross-sectional view of another structure of the semiconductor device according to the embodiment, along cutting line A-A′.

FIG. 11G is a cross-sectional view of another structure of the semiconductor device according to the embodiment, along cutting line A-A′.

FIG. 11H is a cross-sectional view of another structure of the semiconductor device according to the embodiment, along cutting line A-A′.

FIG. 11I is a cross-sectional view of another structure of the semiconductor device according to the embodiment, along cutting line A-A′.

FIG. 11J is a cross-sectional view of another structure of the semiconductor device according to the embodiment, along cutting line A-A′.

FIG. 12 is a top view when the semiconductor device according to the embodiment is mounted.

FIG. 13A is a cross-sectional view depicting a structure in a vicinity of the gate electrode pad 33 of the semiconductor device according to the embodiment.

FIG. 13B is a cross-sectional view depicting the structure in the vicinity of the gate electrode pad 33 of the semiconductor device according to the embodiment.

FIG. 13C is a cross-sectional view depicting the structure in the vicinity of the gate electrode pad 33 of the semiconductor device according to the embodiment.

FIG. 14 is a top view of a conventional semiconductor device.

FIG. 15 is a cross-sectional view of the conventional semiconductor device, along cutting line A-A′.

### DETAILED DESCRIPTION OF THE INVENTION

First, problems associated with the conventional technique are discussed. In the conventional semiconductor device, a barrier metal including a Ti (titanium) film is left on an interlayer insulating film. When Ti remains, the Ti occludes hydrogen and thus, there is a problem in that the threshold of the semiconductor device is likely to decrease.

Here, an overview of an embodiment of the present disclosure is described. A semiconductor device according to the present disclosure has the following features. The semiconductor device includes a first semiconductor layer of a first conductivity type; a gate insulating film in contact with the first semiconductor layer; a gate electrode provided at a first surface of the gate insulating film, opposite to second surface thereof in contact with the first semiconductor layer, an interlayer insulating film provided on the gate electrode; a contact hole penetrating through the interlayer insulating film to a surface of the first semiconductor layer; an upper surface electrode selectively formed in the contact hole and at a surface of the interlayer insulating film; and a sealing film selectively formed at surfaces of the upper surface electrode and the interlayer insulating film. Among a first region covered by the sealing film, a second region adjacent to the first region and in which the upper surface electrode is not covered by the sealing film, and a third region apart from the first region but adjacent to the second region and in which the upper surface electrode is not covered by the sealing film, a first barrier metal containing a first metal is provided between the upper surface electrode and the interlayer insulating film in the second region, while between the upper surface electrode and the interlayer insulating film in the third region is free of the first barrier metal.

According to the above disclosure, the barrier metal is not left on the entire surface of the semiconductor device, but is left only near the polyimide film. As a result, since the amount of Ti in the barrier metal remaining on the interlayer insulating film is small, hydrogen occlusion by Ti is reduced, and a decrease in threshold voltage is reduced. Therefore, the semiconductor device may be manufactured with desirable characteristics and yield.

Further, the semiconductor device according to the present disclosure, in the disclosure above, further includes a second barrier metal having a smaller hydrogen storage capacity than that of the first barrier metal between the upper surface electrode and the interlayer insulating film in the third region.

Further, in the semiconductor device according to the present disclosure, in the disclosure above, the second barrier metal is free of the first metal or contains less of the first metal than does the first barrier metal.

Further, in the semiconductor device according to the present disclosure, in the disclosure above, the second barrier metal is a compound film of the first metal.

Further, in the semiconductor device according to the present disclosure, in the disclosure above, the compound film of the first metal is a nitride film.

Further, in the semiconductor device according to the present disclosure, in the disclosure above, the compound film of the first metal includes a compound film with a semiconductor material.

Further, in the semiconductor device according to the present disclosure, in the disclosure above, the first barrier metal includes a single film of the first metal, and the second barrier metal is free of the single film of the first metal or contains less of the first metal than does the first barrier metal.

Further, in the semiconductor device according to the present disclosure, in the disclosure above, the second barrier metal includes a simple substance of a second metal different from the first metal or a compound film of the second metal.

Further, in the semiconductor device according to the present disclosure, in the disclosure above, the first metal is titanium.

Further, the semiconductor device according to the present disclosure, in the disclosure above, further includes: a second semiconductor layer of a second conductivity type, provided on a surface of the first semiconductor layer; and a transistor region further including a second semiconductor region of the first conductivity type, selectively provided in the second semiconductor layer, at a surface layer thereof.

Further, in the semiconductor device according to the present disclosure, in the disclosure above, the transistor region is provided in the third region while the second region is free of the transistor region.

Further, the semiconductor device according to the present disclosure, in the disclosure above, further includes a lifetime control region.

Further, in the semiconductor device according to the present disclosure, in the disclosure above, the transistor region in the second region is free of the lifetime control region.

Further, the semiconductor device according to the present disclosure, in the disclosure above, further includes a diode region.

Further, the semiconductor device according to the present disclosure, in the disclosure above, further includes in the second region, a non-operating region between the diode region and the transistor region free of the lifetime control region.

Further, in the semiconductor device according to the present disclosure, in the disclosure above, the diode region is provided in the third region, and the second region is free of the diode region.

Further, in the semiconductor device according to the present disclosure, in the disclosure above, the diode region is provided in the second region, and the third region is free of the diode region.

Further, the semiconductor device according to the present disclosure, in the disclosure above, further includes a lifetime control region.

Further, the semiconductor device according to the present disclosure, in the disclosure above, further includes a diode region.

Further, the semiconductor device according to the present disclosure, in the disclosure above, further includes a trench that reaches the first semiconductor layer and the gate electrode is provided in the trench via the gate insulating film.

Further, in the semiconductor device according to the present disclosure, in the disclosure above, the first barrier metal is further provided between the upper surface electrode and the interlayer insulating film in the first region.

Further, the semiconductor device according to the present disclosure, in the disclosure above, further includes a fourth region in contact with the first region and apart from the second region in a region covered by the sealing film, and between the upper surface electrode and the interlayer insulating film in the fourth region is free of the first barrier metal.

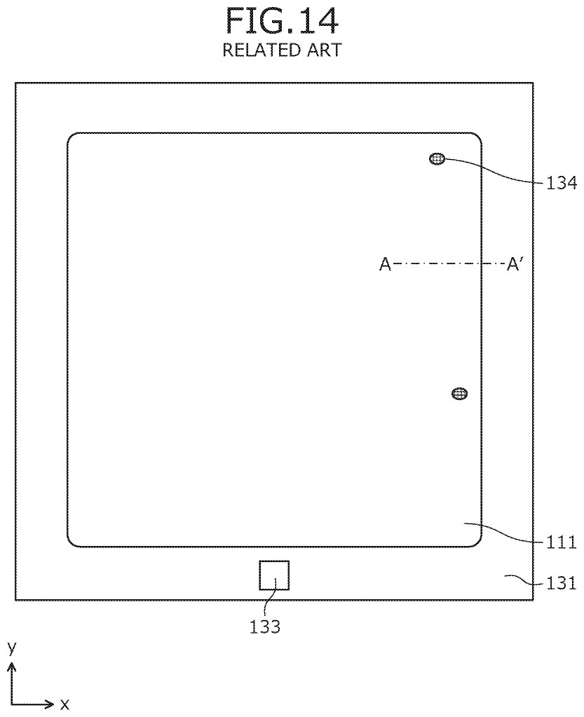

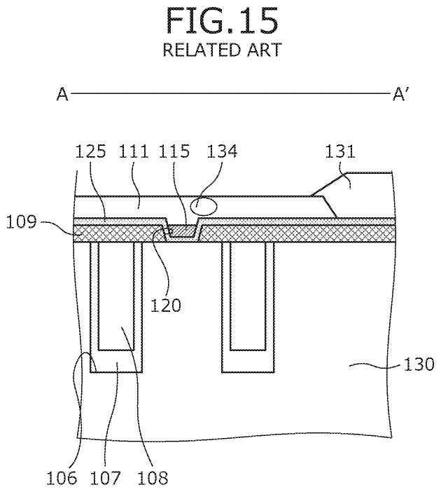

Findings underlying the present disclosure. First, problems associated with a conventional semiconductor device will be described. FIG. 14 is a top view of a conventional semiconductor device. FIG. 15 is a cross-sectional view of the conventional semiconductor device, along cutting line A-A′. Conventionally, a semiconductor device includes a MOS (Metal Oxide Semiconductor) gate in a semiconductor substrate (semiconductor chip) 130, at a front surface thereof. The MOS gate is formed of a gate insulating films 107 and a gate electrodes 108 in a trench 106. An interlayer insulating film 109 for insulating a front electrode 111 and the gate electrodes 108 is provided on the gate electrodes 108. The front electrode 111 is formed of, for example, an Al film, an Al alloy film such as one containing Al—Si or Al—Si—Cu, or copper (Cu).

A contact hole 120 is provided in the interlayer insulating film 109 to electrically connect the front electrode 111 and a semiconductor substrate 130. A plug electrode 115 containing tungsten (W) or copper (Cu) is embedded in the contact hole 120, and a barrier metal 125 for preventing diffusion of ions from the front electrode 111 to the gate insulating films 107 and the gate electrodes 108 is provided on the interlayer insulating film 109. The barrier metal 125 includes, for example, a Ti film and a TiN film.

A polyimide film (passivation film) 131 is formed in a periphery of the front electrode 111 as a protective film for preventing diffusion of ions into the semiconductor device and insulating the semiconductor device.

As described above, in the conventional semiconductor device, the barrier metal 125 is left on the interlayer insulating film 109. A defect 134 may occur in the front electrode 111 due to stress migration during resin sealing assembly of the semiconductor device. Then, when the ions reach the gate insulating films 107 and the gate electrodes 108 via the defect 134, this leads to assembly failure and reliability degradation. When the barrier metal 125 remains on the interlayer insulating film 109, ions do not reach the gate insulating films 107 and the gate electrodes 108, which leads to reduced assembly failures and improved reliability.

On the other hand, when irradiation with hydrogen or helium for forming a lifetime killer control region is performed, the gate insulating films 107 is damaged and defects are generated. These defects are recovered by supplying heat and hydrogen (H₂) to the defect portion in the subsequent annealing treatment. However, in a case where the barrier metal is left on the entire surface of the gate insulating films 107 and the interlayer insulating film 109, there is a problem in that the hydrogen, which is supposed to be supplied to the defect portion by the annealing treatment, is occluded by Ti in the barrier metal and does not reach the defect, the defect is not recovered and the threshold voltage is lowered.

Hereinafter, embodiments of a semiconductor device according to the present disclosure that solves the above-described problems of the conventional semiconductor device will be described in detail with reference to the accompanying drawings. In the present specification and the accompanying drawings, layers and regions prefixed with n or p mean that majority carriers are electrons or holes, respectively. Further, + and − appended to n and p mean that the dopant concentration is higher and lower, respectively, than layers and regions without + and −. In the following description of the embodiments and the accompanying drawings, components that are the same are denoted by the same reference numerals, and redundant description thereof will be omitted. The term “the same” or “equivalent” means within 5% with consideration of manufacturing variation.

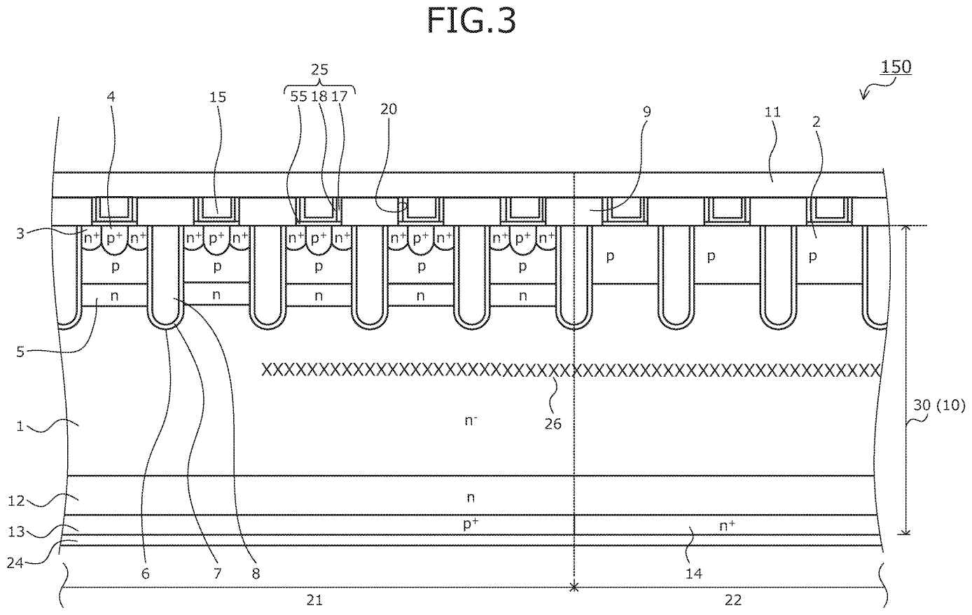

FIG. 3 is a cross-sectional view depicting a structure of a semiconductor device according to an embodiment. The structure of the semiconductor device according to the embodiment will be described taking a trench type RC-IGBT 150 as an example. The semiconductor device according to the embodiment depicted in FIG. 3 is the RC-IGBT 150 in which an IGBT having a trench structure and a diode connected in anti-parallel to the IGBT are integrated on a single semiconductor substrate (semiconductor chip) 30. The RC-IGBT 150 includes an active region, which is a region through which a current flows during an on-state, and an edge termination region surrounding a periphery of the active region in a plan view. FIG. 3 depicts only the active region.

In the RC-IGBT 150, an IGBT region (transistor region) 21 serving as an IGBT operating region and an FWD region (diode region) 22 serving as a diode operating region are provided in parallel on the single semiconductor substrate 30 having the active region.

In the active region, in a semiconductor substrate 30, an n-type accumulation layer 5 may be provided in an n⁻-type drift layer (first semiconductor layer of a first conductivity type) 1, at a front surface (first main surface) thereof. The n-type accumulation layer 5 is a so-called charge storage layer (CSL) that reduces the spreading resistance of carriers. A p-type base region (second semiconductor layer of a second conductivity type) 2 is provided on the n-type accumulation layer 5 from the IGBT region 21 to the FWD region 22. The p-type base region 2 functions as a p-type anode region in the FWD region 22. Trenches (grooves) 6 penetrating through the p-type base region 2 and reaching the n⁻-type drift layer 1 are provided. The trenches 6 are provided in the IGBT region 21 and the FWD region 22, and n⁺-type emitter regions (first semiconductor regions of the first conductivity type) 3 are provided on both sides of the IGBT region 21. The trenches 6 are arranged at predetermined intervals, for example, in a striped pattern in a plan view, thereby dividing the p-type base region 2 into multiple regions (mesa portions). Inside the trenches 6, respectively, a gate insulating films 7 are provided along inner walls of the trenches 6, and gate electrodes 8 are provided on the gate insulating films 7, respectively. The gate electrodes 8 are connected to a gate pad and receive a gate potential from an external circuit connected to the gate pad. A portion of the trenches 6 may be dummy trenches in which the gate electrodes 8 thereof are not connected to the gate pad and are fixed to the potential of the emitter electrode. In the present example, the dummy trenches may also be described as the trenches 6 when unnecessary. In another example, the trenches 6 may be omitted in the FWD region 22.

In the IGBT region 21, n⁺-type emitter regions 3 are selectively provided in the mesa portions of the p-type base region 2. The n⁺-type emitter regions 3 face the gate electrodes 8 across the gate insulating films 7 provided at the inner walls of the trenches 6. In each mesa portion, p⁺-type contact regions 4 may be provided. In this case, the n⁺-type emitter regions 3 and the p⁺-type contact regions 4 are in contact with each other. In FIG. 3, the n⁺-type emitter regions 3 and the p⁺-type contact regions 4 are arranged in a direction in which the trenches 6 are arranged repeatedly adjacent to each other. However, the present disclosure is not limited hereto, and the n⁺-type emitter regions 3 and the p⁺-type contact regions 4 may be repeatedly alternate with each other in a direction in which the trenches 6 extend (longitudinal direction of the trenches 6). In the FWD region 22, the p-type base region 2 is free of the n⁺-type emitter regions 3 and the p⁺-type contact regions 4. A front electrode (upper surface electrode) 11 is in contact with the n⁺-type emitter regions 3 via contact holes 20, and is electrically insulated from the gate electrodes 8 by an interlayer insulating film 9. Some of the mesa portions may be free of the contact holes 20 formed thereabove. Sidewalls of the contact holes 20 may be vertical or tapered. An opening may be selectively provided in the n⁺-type emitter regions 3, and the front electrode 11 and the p-type base region 2 may be electrically connected to each other in the opening. When the p⁺-type contact regions 4 is provided, the front electrode 11 and the p⁺-type contact regions 4 may be electrically connected to each other. The front electrode 11 functions as an emitter electrode in the IGBT region 21 and functions as an anode electrode in the FWD region 22. Between the front electrode 11 and the interlayer insulating film 9, for example, a Ti film 17 and a TiN film 18 are provided as a barrier metal 25 that prevents diffusion of ions from the front electrode 11 in a direction to the gate electrodes 8. The Ti film 17 at the bottom of the contact holes 20 may be present as a titanium silicide film 55 by forming an alloy with the semiconductor substrate 30. The p-type base region 2 and the p⁺-type contact regions 4 may have a plug region (not depicted) in which the dopant concentration is further increased in at least a part of the region immediately below the contact holes 20.

Alternatively, contact plugs may be embedded in the contact holes 20 formed in the interlayer insulating film 9. The contact plugs are formed of, for example, a metal film containing tungsten (W) or copper (Cu) having high embeddability. The front electrode 11 is constituted by an Al film, an Al alloy film such as one containing Al—Si or Al—Si—Cu, or copper (Cu). When the cell pitch is wide, the contact holes 20 may be filled with the front electrode 11 without forming the contact plugs. Hereinafter, the contact plugs or the front electrode 11 in the contact holes 20 is referred to as plug electrodes 15. A polyimide film (passivation film, sealing film) 31 is formed surrounding the front electrode 11 in a plan view as a protective film for preventing diffusion of ions into the semiconductor device and insulating the semiconductor device.

In the n⁻-type drift layer 1, an n-type field stop (FS) layer 12 is provided near the substrate back surface. The n-type FS layer 12 has a function of suppressing expansion of a depletion layer that spreads from pn junctions between the p-type base region 2 and the n⁻-type drift layer 1 toward a later-described p⁺-type collector region 13 during an off-state.

In the n⁻-type drift layer 1, in the FWD region 22, a lifetime control region 26 may be provided at a position shallower from the front surface of the n⁻-type drift layer 1 than is the n-type FS layer 12. The lifetime control region 26 is formed by introducing a lattice defect (indicated by x) such as a vacancy (V) serving as a lifetime killer by irradiation with hydrogen (H) or helium (He). Even when lattice defects are formed over a wide range in a thickness direction of the semiconductor substrate 30 by electron beam irradiation or the like, it may be considered that the lifetime control region 26 is formed at a shallow position from the front surface. By forming the lifetime control region 26, loss and surge during switching in the device may be reduced. In particular, the lifetime control region 26 has a function of reducing holes injected from the p-type base region 2 and the p⁺-type contact regions 4 in a vicinity of an n⁺-type cathode region 14 of the FWD region 22. Therefore, the lifetime control region 26 may be provided in a range centered on the FWD region 22. In the present example, the lifetime control region 26 extends from the FWD region 22 to a vicinity of the boundary between the IGBT region 21 and the FWD region 22. In another example, the lifetime control region 26 may be omitted in a part of or at the entire surface of the FWD region 22, may be provided at the entire surface of the IGBT region 21, or may be omitted at the entire surface of the IGBT region 21, and the lifetime control region 26 may extend to the chip end of the edge termination region. The lifetime control region 26 may be omitted.

In the n⁻-type drift layer 1, the p⁺-type collector region 13 is provided in the IGBT region 21 and the n⁺-type cathode region 14 is provided in the FWD region 22 at a position shallower from the back surface (second main surface) of the n⁻-type drift layer 1 than is the n-type FS layer 12. The n⁺-type cathode region 14 is adjacent to the p⁺-type collector region 13. A back electrode 24 is provided on the surfaces of the p⁺-type collector region 13 and the n⁺-type cathode region 14. The back electrode 24 functions as a collector electrode in the IGBT region 21 and functions as a cathode electrode in the FWD region 22.

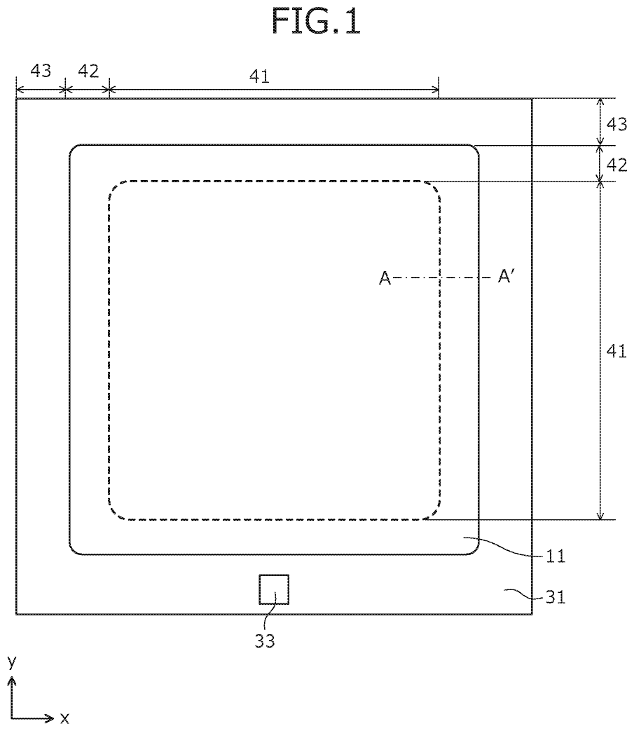

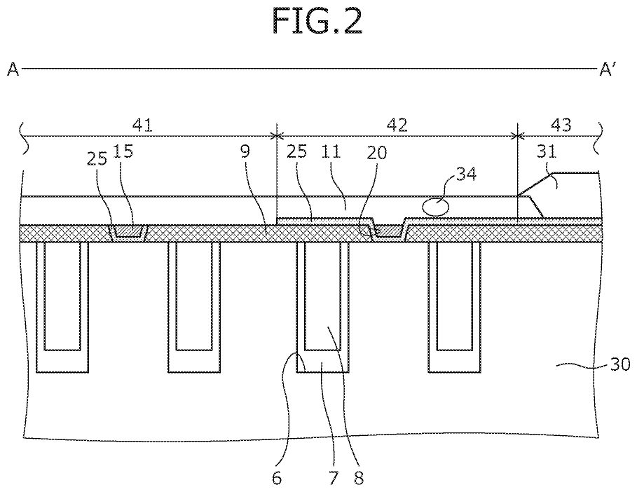

FIG. 1 is a top view of the semiconductor device according to the embodiment. FIG. 2 is a cross-sectional view of the semiconductor device according to the embodiment, along cutting line A-A′. As depicted in FIGS. 1 and 2, the semiconductor device according to the embodiment includes, in a top view, a first region 43 covered by the polyimide film 31, a second region 42 in which the front electrode 11 is not covered by the polyimide film 31 and is adjacent to the first region 43, and a third region 41 in which the front electrode 11 is not covered by the polyimide film 31, is not adjacent to the first region 43, and is adjacent to the second region 42.

As depicted in FIG. 2, in the first region 43 and the second region 42, the front electrode 11 includes the barrier metal 25 on the surface of the interlayer insulating film 9, and in the third region 41, the front electrode 11 does not include the barrier metal 25 on the surface of the interlayer insulating film 9. As described above, in the embodiment, the barrier metal 25 is not left over the entire surface of the semiconductor device, but is left only near the polyimide film 31 where the defect 34 is likely to occur. In the third region 41, when the plug electrodes 15 are formed with the same composition as that of the front electrode 11 concurrently therewith, the inside of the contact holes 20 may not be provided with the barrier metal 25, and a silicide may or may not be formed at the bottoms of the contact holes 20. The interlayer insulating film 9 may have a step at a boundary between the second region 42 and the third region 41 adjacent thereto. In the first region 43, a region not covered by the front electrode 11 may be free of the barrier metal 25.

In FIG. 1, the outer shapes of the second region 42 and the third region 41 are substantially rectangular. However, in a case where the polyimide film 31 has a convex shape in a plan view such that a gate finger, a runner of a temperature sensing diode, an auxiliary pad, or the like formed in the same layer as the front electrode 11 protrudes toward the active region, in a case where the polyimide film 31 is provided so as to cross the center of the chip without being limited to the outer periphery of the chip, or in a case where the polyimide film 31 is scattered inside the chip, the barrier metal 25 on the interlayer insulating film 9 is also left in the periphery of the polyimide film 31 in the convex shape or inside the chip.

As a result, since the amount of Ti in the barrier metal 25 left on the interlayer insulating film 9 is small, hydrogen occlusion by Ti is reduced, and a decrease in the threshold voltage is reduced. Therefore, the semiconductor device may be manufactured with desirable characteristics and yield. This configuration is particularly effective in a product in which the lifetime control region 26, which causes more damage to the gate electrodes 8, is formed.

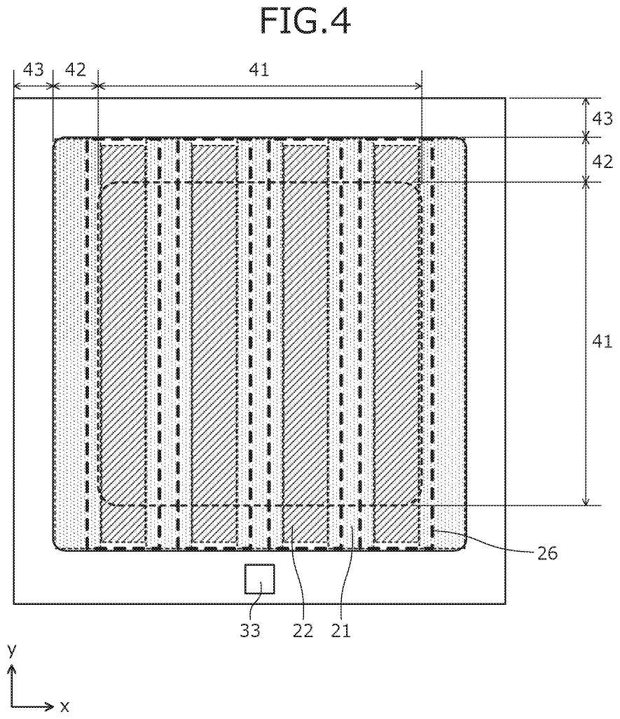

FIG. 4 is a top view of a first example of the semiconductor device according to the embodiment. In FIG. 4, in the RC-IGBT 150, the rectangular IGBT regions 21 and the rectangular FWD regions 22 along the longitudinal direction (y direction) of the trenches 6 are alternately arranged in a repeating direction (x direction) of the trenches 6. The lifetime control region 26 is provided in all the FWD regions 22 and parts of the IGBT regions 21. In the top views in FIG. 4 and subsequent figures, a thick broken line indicates a boundary of a region where the lifetime control region 26 is provided. In this example, the lifetime control region 26 is provided in regions surrounded by a thick broken line. A region surrounded by a thin broken line is the third region 41, a region outside the third region 41 is the second region 42, and an outermost region is the first region 43. In this structure, the gate electrodes 8 and the gate electrode pad 33 may be connected by a gate finger (not depicted) in an outer periphery, provided in the first region 43.

In the example depicted in FIG. 4, the IGBT regions 21 and the FWD regions 22 are drawn in the third region 41 and the second region 42, and are not drawn in the first region 43. However, the IGBT regions 21 or the FWD regions 22 may also be formed in the first region 43. The same applies to the top views hereinafter. End portions of the trenches 6 are located in the first region 43 and are connected to the gate finger (not depicted) in the outer periphery.

The lifetime control region 26 is provided in all the FWD regions 22 and parts of the IGBT regions 21 in a vicinity of the FWD regions 22, and the boundary of the lifetime control region 26 in the y direction from the FWD region 22 is provided at the boundary between the second region 42 and the first region 43, but is not limited hereto. The boundary of the lifetime control region 26 may be provided in the first region 43 or may be provided in the second region 42. In order to improve the reverse recovery characteristics by separating the n⁺-type cathode region 14 from the peripheral gate finger and p⁺-type well region 29 of the edge termination region, a partial region of the end portion of the FWD regions 22 in the y direction may be a non-operating region. The non-operating region is a region that does not function as an IGBT or an FWD. For example, the front surface is a region of the p-type base region 2 and the back surface is a region of the p⁺-type collector region 13. The lifetime control region 26 may be omitted up to a region where the p⁺-type well region 29 is present by widening the non-operating region. Although the gate insulating films 7 may be damaged by irradiation with hydrogen or helium when the lifetime control region 26 is formed, a portion covered by the barrier metal 25 is reduced as compared with a case where the barrier metal 25 is left on the entire surface and thus, a decrease in the threshold voltage is reduced.

However, it is considered that a decrease in the threshold voltage is likely to occur near the barrier metal 25 and there is a possibility that a different threshold voltage is set for each region, which causes a problem. In this case, the operation timing may be adjusted. In the IGBT regions 21 having the lifetime control region 26 of the second region 42, threshold compensation may be performed by increasing the dopant concentration of the p-type base region 2 or increasing the thickness of the gate insulating films 7 as compared with the other IGBT regions 21. Alternatively, a gate signal different from that of the other IGBT regions 21 may be applied to adjust the turn-on and turn-off operation timings. The adjustment of the threshold voltage and the operation timing may be gradually changed according to the degree of influence. Alternatively, in the second region 42 where the barrier metal 25 is left, the IGBT region 21 having the lifetime control region 26 may be formed as a non-operating region. These adjustments may be performed not only in the IGBT region 21 of the second region 42 but also in a portion of the IGBT region 21 of the third region 41 that is affected by being close to the second region 42. Further, also in the second region 42, application may be omitted to a portion that is close to the third region 41 and thus, has a slight influence.

In addition, the IGBT regions 21 having the lifetime control region 26 may be omitted in the second region 42 to reduce the decrease in the threshold voltage. In an example described below, when the lifetime control region 26 is provided in the FWD regions 22 and parts of the IGBT regions 21 close to the FWD region 22, the respective regions are arranged so that the IGBT regions 21 having the lifetime control region 26 are not provided in the second region 42. Also in the examples, the IGBT regions 21 having the lifetime control region 26 may be omitted in a portion of the IGBT regions 21 of the third region 41 which is affected by being close to the second region 42, and the IGBT regions 21 having the lifetime control region 26 may be provided in a portion of the second region 42 which is slightly affected by being close to the third region 41.

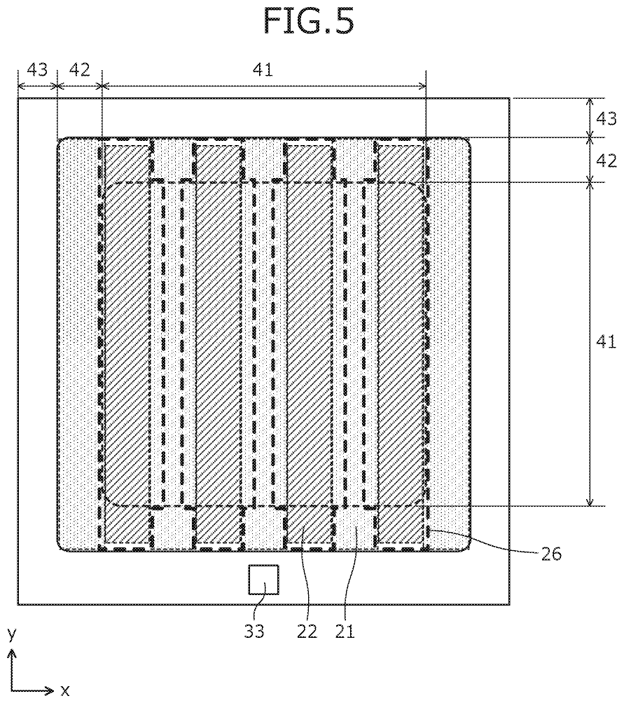

FIG. 5 is a top view of a second example of the semiconductor device according to the embodiment. As in the example depicted in FIG. 4, in the RC-IGBT 150, the rectangular IGBT regions 21 and the rectangular FWD regions 22 along the longitudinal direction (y direction) of the trenches 6 are alternately arranged in the repeating direction (x direction) of the trenches 6. The lifetime control region 26 is provided in regions surrounded by a thick broken line, and is provided in all the FWD regions 22 and parts of the IGBT regions 21. In this example, the lifetime killer is not inserted into the IGBT regions 21 in the second region 42 immediately below the barrier metal 25 or in a vicinity thereof, even a vicinity of the FWD regions 22 is free of the lifetime control region 26. The lifetime adjustment region 26 is provided in the IGBT regions 21 of the third region 41. With such an arrangement, it is possible to reduce the decrease in the threshold while improving the characteristics during reverse recovery.

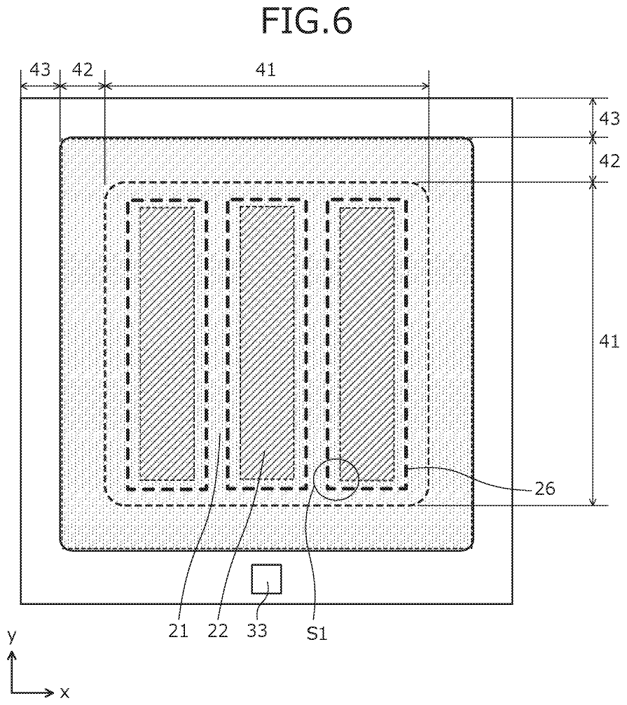

FIG. 6 is a top view of a third example of the semiconductor device according to the embodiment. In FIG. 6, in the RC-IGBT 150, the rectangular FWD regions 22 along the longitudinal direction of the trenches 6 are alternately arranged in the repeating direction of the trenches 6, and the IGBT region 21 is provided outside the FWD regions 22. In FIG. 6, the lifetime control region 26 is provided in all the FWD regions 22 and parts of the IGBT region 21; in the second region 42, the FWD regions 22 are not formed and the lifetime control region 26 is not provided in the IGBT region 21. As described above, the lifetime control region 26 is not provided in the IGBT region 21 in the second region 42, and the decrease in the threshold voltage may be reduced. In this structure, the gate electrodes 8 and the gate electrode pad 33 may be connected by a gate finger (not depicted) provided in the first region 43, in the outer periphery.

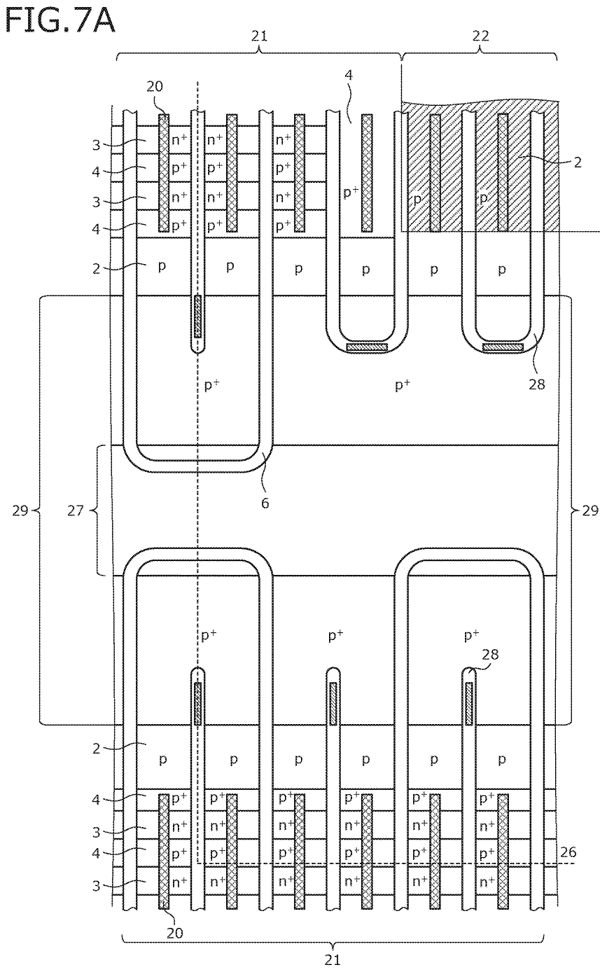

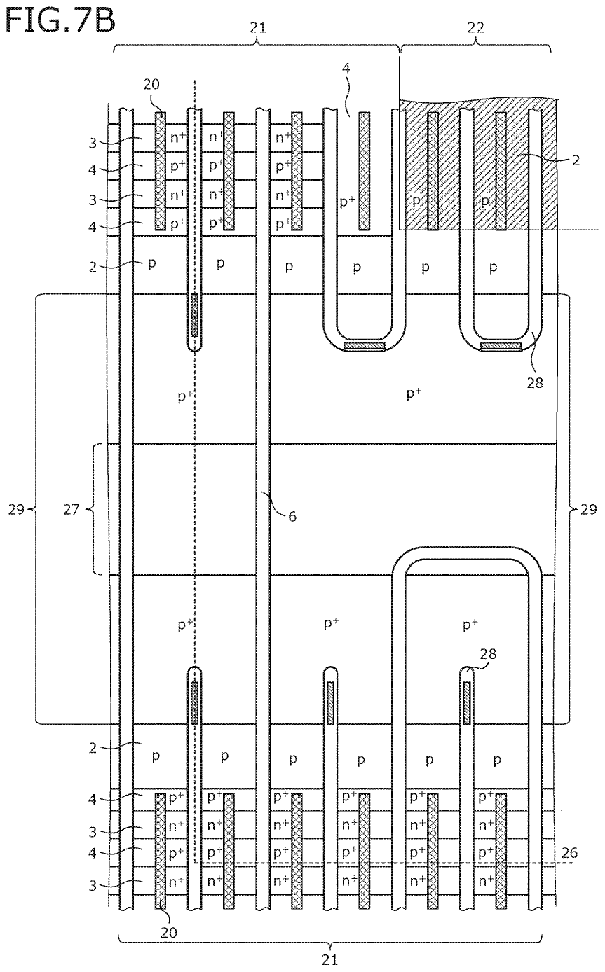

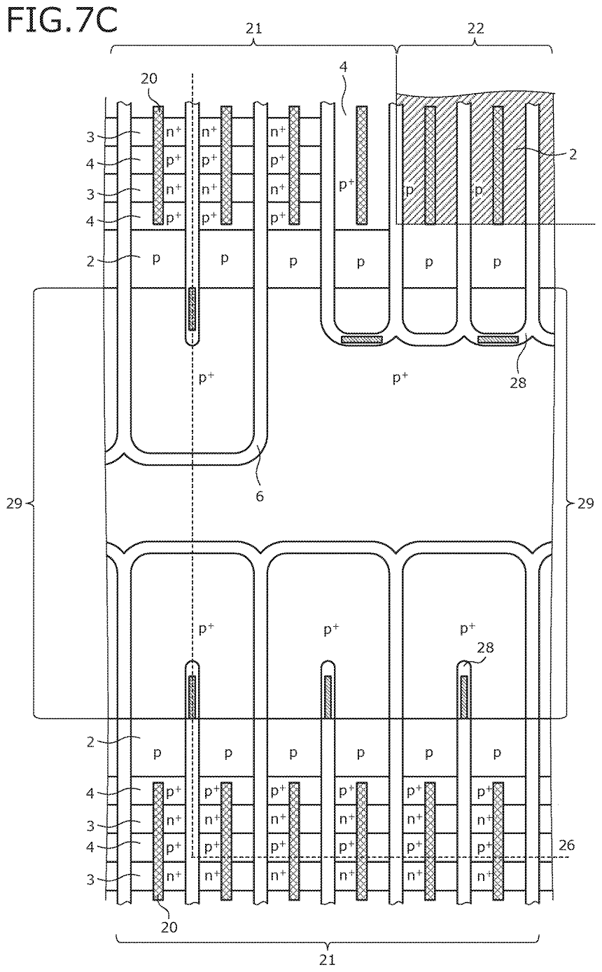

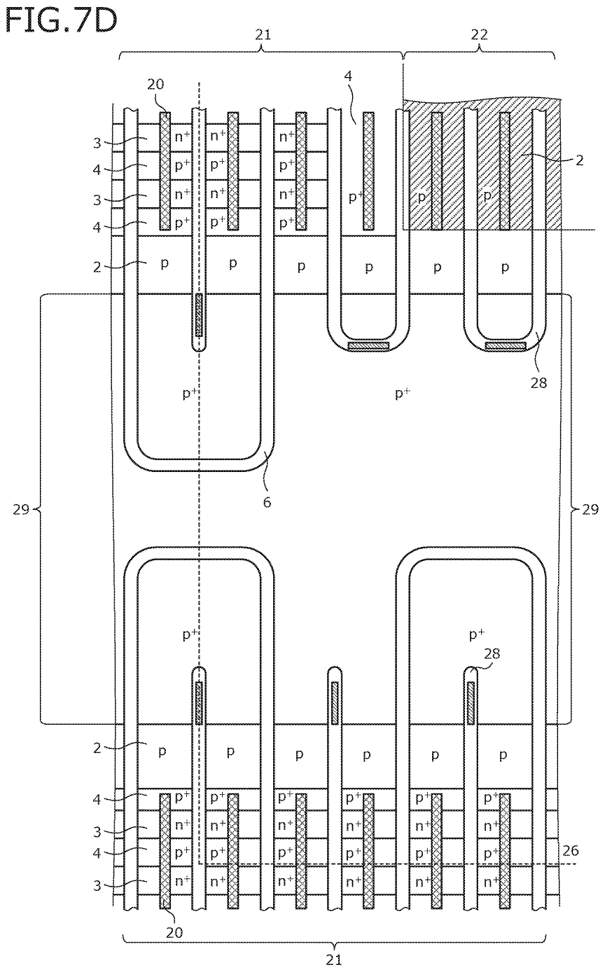

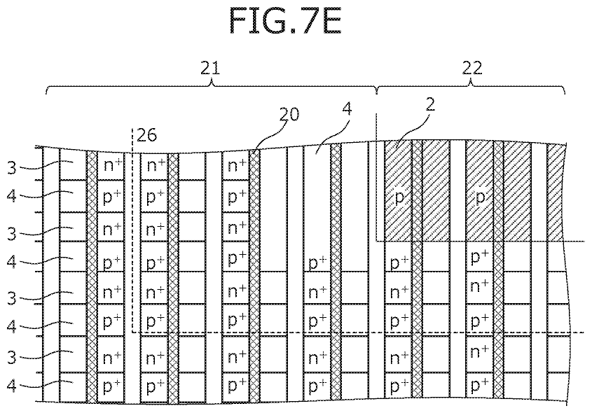

FIG. 7A is an enlarged top view of a region S1 of the third example of the semiconductor device according to the embodiment. In FIG. 7A, the front electrode 11 and the interlayer insulating film 9 are not depicted, and only the contact holes 20 are depicted, and the structure of layers lower than these is depicted. FIG. 7A is a top view of a structure in which a poly-runner 27 connecting the gate electrodes 8 and the gate finger is provided at the boundary between the IGBT region 21 and the FWD region 22 in the y direction.

The trenches 6 of the IGBT region 21 are connected to the poly-runner 27. The poly-runner 27 is provided on the p⁺-type well region 29 via an insulating film. The insulating film may be formed by forming the gate insulating films 7 and being left on the semiconductor substrate 30. The poly-runner 27 may be formed simultaneously with the gate electrodes 8 and left on the semiconductor substrate 30 as is. An end portion of each dummy trench 28 extends to the p⁺-type well region 29. The upper surface of the poly-runner 27 is covered by the interlayer insulating film 9, and the upper surface of the poly-runner 27 is covered by the front electrode 11 connected to the IGBT region 21 and the FWD regions 22. The p⁺-type well region 29 may be omitted.

A boundary region may be provided in the IGBT region 21 adjacent to the FWD regions 22 in the x direction. The boundary region is a structure for connecting different structures of the IGBT region 21 and the FWD regions 22 so as to have good characteristics, and a structure different from the structure of a normal IGBT region may be provided. In this example, in a region sandwiched between the dummy trenches 28 on both sides thereof, the p⁺-type contact regions 4 are provided at the front surface thereof and the n⁺-type emitter regions 3 are not provided, and a region serving as the p⁺-type collector region 13 is provided at the back surface thereof. In another example, the front surface may be the p-type base region 2 and the back surface may be the p⁺-type collector region 13, and the p-type base region 2 and the p⁺-type collector region 13 may be formed in a region sandwiched between the trenches 6 or the dummy trenches 28. Or the boundary region may be omitted.

The lifetime control region 26 may be provided up to the IGBT region 21 adjacent thereto in the x direction and the y direction. In another example, the poly-runner 27 and the n⁺-type cathode region 14 (the p⁺-type well region 29 and the n⁺-type cathode region 14) may be sufficiently apart from each other as a non-operating region (the front surface is the p-type base region 2 and the back surface is the p⁺-type collector region 13) so that the lifetime control regions 26 do not overlap the p⁺-type well region 29 or the lifetime control region 26 overlaps a range up to the p⁺-type well region 29, and the lifetime control region 26 may be omitted in the IGBT region 21 adjacent in the y direction. In such a case, the IGBT region 21 may be omitted in the third region 41. That is, boundaries between the IGBT region 21 and the FWD regions 22 may coincide with the boundary between the third region 41 and the second region 42.

FIG. 7B is an enlarged top view of a different example of the region S1 of the third example of the semiconductor device according to the embodiment. FIG. 7B is a top view of a structure in which the poly-runner 27 connecting the gate electrodes 8 and the gate finger is provided at the boundaries between the IGBT region 21 and the FWD regions 22 in the y direction. FIG. 7B depicts a structure in which the trenches 6 are shared in adjacent regions of the IGBT region 21 where the poly-runner 27 is interposed said adjacent regions in the y direction. At locations where regions of the IGBT region 21 are adjacent to each other in the y direction, the n⁺-type emitter regions 3 and the p⁺-type contact regions 4 may be provided as an operating region instead of the p⁺-type well region 29 as a structure in which the poly-runner 27 is not extended. The other regions may be the same as the example described with reference to FIG. 7A.

FIG. 7C is an enlarged top view of a different example of the region S1 of the third example of the semiconductor device according to the embodiment. FIG. 7C is a top view of a structure in which the poly-runner 27 connecting the gate electrodes 8 and the gate finger is provided at the boundaries between the IGBT region 21 and the FWD regions 22 in the y direction. In FIG. 7C, the end portions of the trenches 6 adjacent to each other in the x direction are connected to form the poly-runner 27. The connection of the trenches 6 is not limited to a T-shape, and may be a cross or other structures. Similarly, the dummy trenches 28 may be connected to each other in the x direction. The other regions may be the same as those in the example described with reference to FIG. 7A.

FIG. 7D is an enlarged top view of a different example of the region S1 of the third example of the semiconductor device according to the embodiment. FIG. 7D is a top view of a structure in which the poly-runner 27 is not provided but the trenches 6 are separate. The IGBT region 21 that is not adjacent to the FWD regions 22 in the y direction may be an operating region in which the n⁺-type emitter regions 3 and the p⁺-type contact regions 4 are provided without forming the p⁺-type well region 29 and without providing the end portions of the trenches 6 and the dummy trench 28. The other regions may be the same as those in the example described with reference to FIG. 7A.

FIG. 7E is an enlarged top view of a different example of the region S1 of the third example of the semiconductor device according to the embodiment. FIG. 7E is a top view of a structure that does not isolate trenches 6. As described above, the IGBT region 21 and the FWD regions 22 may have the same trenches 6 and the same dummy trenches 28. However, the FWD is affected by the gate operation. The other regions may be the same as those in the example described with reference to FIG. 7A.

The regions in contact with the FWD regions 22 in the y direction may not be the normal IGBT region 21 but may be entirely formed as a non-operating region. In this case, it is not necessary to provide the trenches 6 connected to the gate finger, and the dummy trenches 28 may be provided. In this case, it is not necessary to separate the dummy trenches 28 at the boundary of the FWD region 22, that is, at the boundary between the effective FWD region and the non-operating region, and the dummy trenches 28 may extend to the p⁺-type well region 29 provided in the first region 43 at the outer periphery.

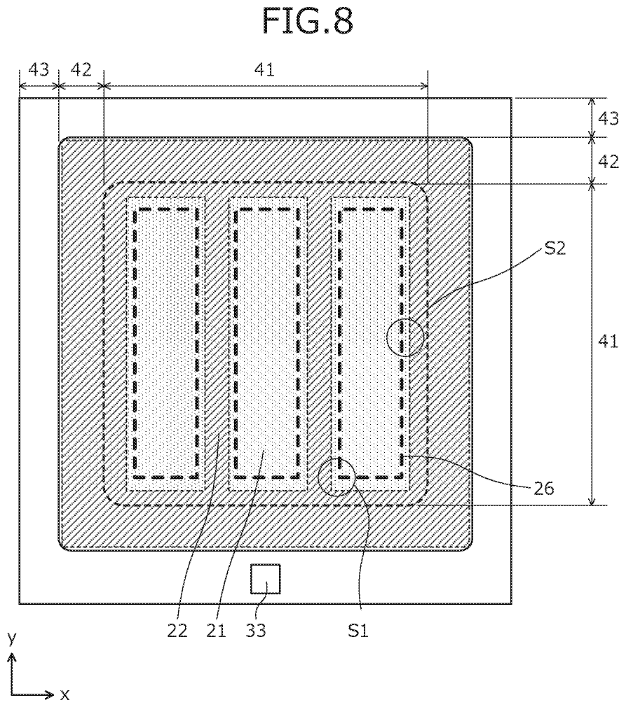

FIG. 8 is a top view of a fourth example of the semiconductor device according to the embodiment. In FIG. 8, in the RC-IGBT 150, rectangular IGBT regions 21 along the longitudinal direction of the trenches 6 are alternately arranged in the repeating direction of the trenches 6, and FWD region 22 is provided outside the IGBT regions 21. In FIG. 8, in the present example, the lifetime control region 26 is provided in the active region except for regions surrounded by a thick broken line. The lifetime control region 26 is provided in the entire FWD region 22 and a part of each of the IGBT regions 21, and the IGBT regions 21 are not provided in the second region 42. As described above, since the IGBT region 21 having the lifetime control region 26 is not provided in the second region 42, a decrease in the threshold voltage may be reduced.

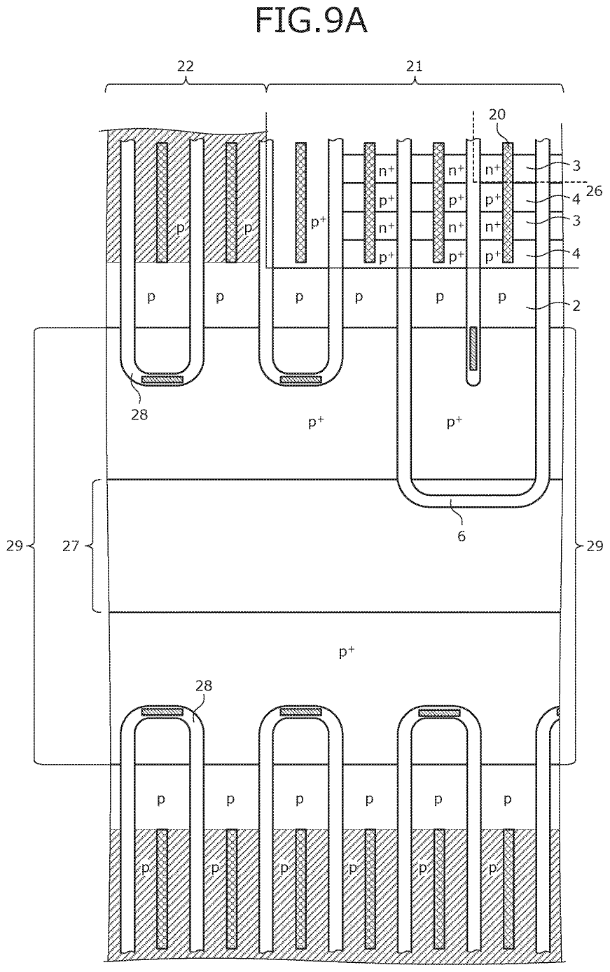

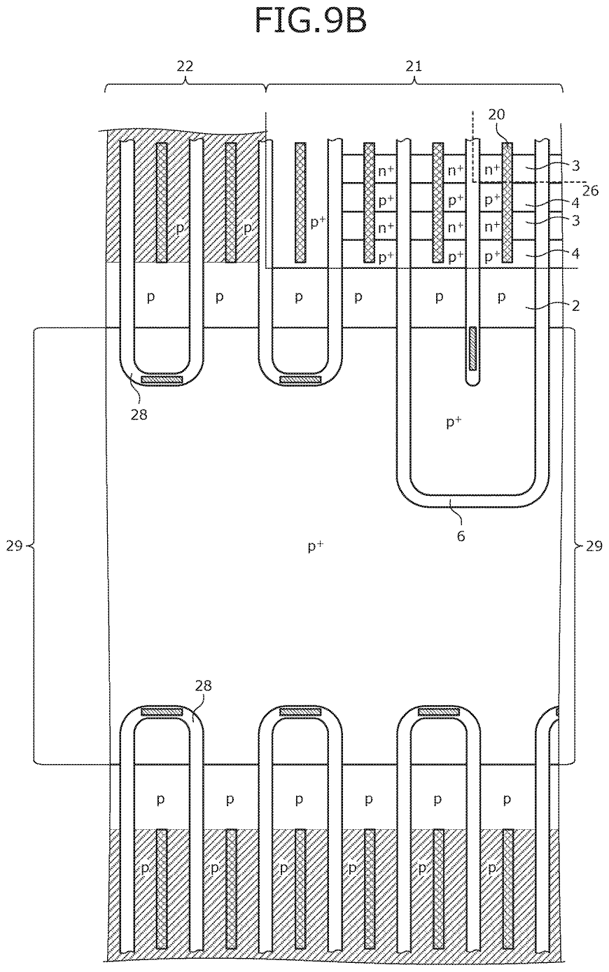

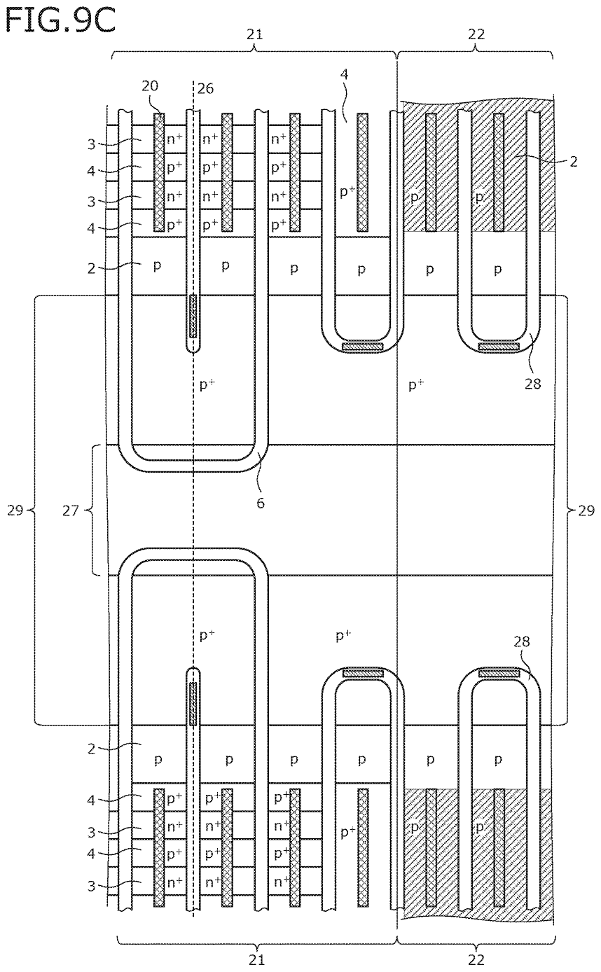

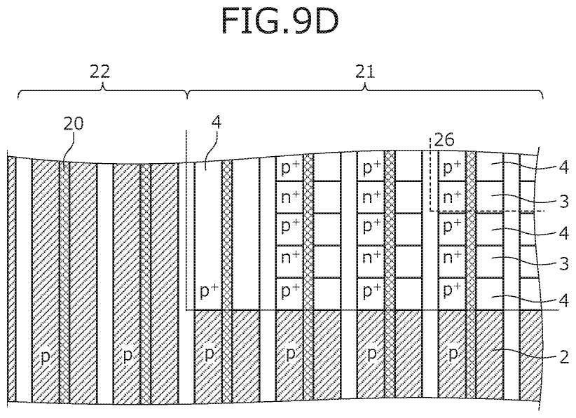

FIG. 9A is an enlarged top view of the region S1 of the fourth example of the semiconductor device according to the embodiment. FIG. 9A is a top view of a structure in which a poly-runner 27 connecting the gate electrodes 8 and the gate finger is provided at the boundaries between the IGBT regions 21 and the FWD region 22 in the y direction. This example corresponds to the example described with reference to FIG. 7A in the second embodiment, and the description of the same points as those in FIG. 7A will be omitted.

The lifetime control region 26 may be provided up to the IGBT regions 21 adjacent to portions of the FWD region 22 in the x direction and the y direction. In another example, the poly-runner 27 and the cathode region (the p⁺-type well region 29 and the n⁺-type cathode region 14) may be sufficiently apart from each other as a non-operating region (the front surface is the p-type base region 2 and the back surface is the p⁺-type collector region 13) so that the lifetime control regions 26 do not extend to the p⁺-type well region 29 or the lifetime control regions 26 extend to the p⁺-type well region 29, and the lifetime control region 26 may be omitted in the IGBT region 21 adjacent in the y direction. The FWD region 22 may be omitted in the third region 41. That is, the boundaries between the IGBT regions 21 and the FWD region 22 may coincide with the boundary between the third region 41 and the second region 42. In another example, the lifetime control region 26 may also be provided on the surfaces of all the IGBT regions 21. Also in this case, the IGBT regions are is not provided in the second region 42, so that the decrease in the threshold voltage is suppressed.

In the arrangement of the embodiment depicted in FIG. 8, when the dummy trenches 28 are provided and the trenches 6 are omitted in the FWD region 22, the gate electrodes 8 of the IGBT regions 21 in the third region 41 and the gate electrode pad 33 cannot be connected by the gate finger provided in the first region 43 in the outer periphery. The gate electrodes 8 of the IGBT regions 21 in the third region 41 and the gate electrode pad 33 may be connected to each other by extending the poly-runner 27 depicted in FIG. 9A to the first region 43 and connecting the poly-runner 27 to the gate finger in the outer periphery. Also in FIG. 9A, the configuration of the poly-runner 27, the trenches 6, and the dummy trenches 28 may be the same as that depicted in FIG. 7C.

FIG. 9B is an enlarged top view of a different example of the region S1 of the second example of the semiconductor device according to the embodiment. FIG. 9B is a top view of a structure in which the poly-runner 27 is not provided but the trenches 6 are separate. Portions of the FWD region 22 not adjacent to the IGBT regions 21 in the y direction may be made active without forming the p⁺-type well region 29, without providing the end portions of the trenches 6 and the dummy trenches 28, and with the p-type base region 2 placed.

In the arrangement of the embodiment depicted in FIG. 8, when the dummy trenches 28 are provided and the trenches 6 are not provided in the FWD region 22, the gate electrodes 8 of the IGBT regions 21 in the third region 41 and the gate electrode pad 33 cannot be connected by the gate finger provided in the first region 43 in the outer periphery. As depicted in FIG. 9C, when the poly-runner 27 is provided between the IGBT regions 21 and the FWD region 22 and does not extend to the first region 43 to be connected to the gate finger in the outer periphery, the poly-runner 27 is disposed in the IGBT regions 21 and extends to the first region 43 to be connected to the gate finger in the outer periphery.

FIG. 9C is an enlarged top view of the region S2 of the fourth example of the semiconductor device according to the embodiment. As depicted, the poly-runner 27 may be disposed in the IGBT regions 21. For example, in the IGBT regions 21 facing each other in the y direction with the poly-runner 27 interposed therebetween, the poly-runner 27, the trenches 6, and the dummy trenches 28 may have the same forms as those depicted in FIGS. 7B and 7C or other forms. The structure in which the poly-runner 27 is disposed in the IGBT regions 21 is not limited to a case where the poly-runner 27 is not disposed by separating the trenches between the IGBT regions 21 and the FWD region 22, and may be applied to a case of a different boundary. The present disclosure is not limited to the fourth example depicted in FIG. 8, and may be applied to the examples depicted in FIGS. 1, 4, 5, and 6.

FIG. 9D is an enlarged top view of a different example of the region S1 of the second example of the semiconductor device according to the embodiment. FIG. 9D is a top view of a structure that does not isolate the trenches 6. As described above, the IGBT regions 21 and the FWD region 22 may have the same trenches 6 and the same dummy trenches 28. However, the FWD is affected by the gate operation. In this case, the gate electrodes 8 of the IGBT regions 21 and the gate electrode pad 33 may be connected without disposing the poly-runner 27 in the IGBT region 21 as depicted in FIG. 9C.

The regions in contact with the IGBT regions 21 in the y direction may not be the normal FWD region 22 but may be entirely formed as a non-operating region. In this case, it is not necessary to separate the trenches 6 at the boundary of the IGBT region 21, that is, at the boundary between the effective IGBT region and the non-operating region, the trenches 6 may be extended and connected to the gate finger provided in the first region 43 in the outer periphery.

As an example of the semiconductor device according to another embodiment, the effective IGBT region 21 may be omitted in the second region 42 and the first region 43 regardless of the lifetime control region 26. That is, a non-operating region may be formed in such a manner that only the dummy trenches 28 are formed at the front surface, the p-type base region 2 or the p⁺-type contact regions 4 are provided at the front surface without providing the n⁺-type emitter regions 3, and the p⁺-type collector region 13 is provided at the back surface. Also in the third region 41, the effective IGBT region 21 may be omitted in a region that is close to the second region 42 and greatly affected by the barrier metal, and the effective IGBT region 21 may be provided in a region that is close to the third region 41 and is slightly affected by the barrier metal in the second region 42. The effective FWD region 22 may be omitted in the second region 42.

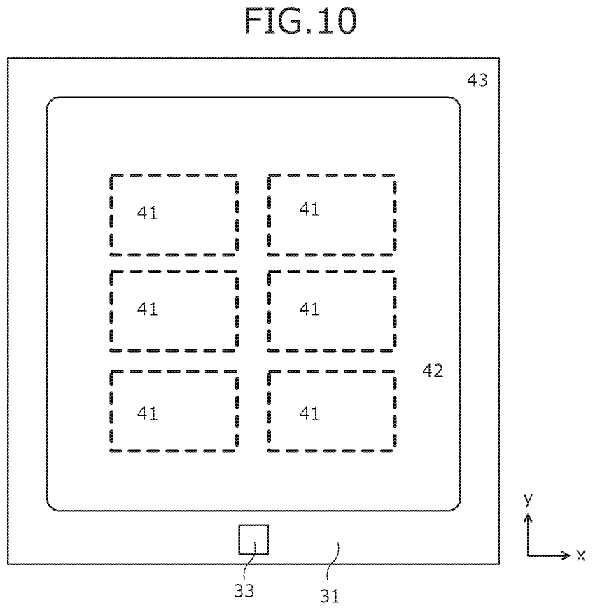

FIG. 10 is a top view of another structure of the semiconductor device according to the embodiment. In the present example, multiple third region 41 are provided in the opening of the emitter electrode pad, and the second region 42 is provided therebetween. That is, one second region 42 is not provided in an annular shape but is provided in a mesh shape. Also in such a case, by providing the third region 41, the barrier metal is reduced, and the occlusion of hydrogen is reduced, whereby the decrease in the threshold voltage is suppressed.

Next, a method of manufacturing the semiconductor device according to the embodiment will be described. The method described below is an example and the present disclosure is not limited hereto. The method may be performed by appropriately changing the order, or the members to be used may be appropriately changed. When a temperature sensing diode or the like is provided, other appropriate manufacturing steps may be added. First, the n⁻-type drift region 1 is formed in an n⁻-type semiconductor wafer 10 to be the semiconductor substrate 30. The n⁻-type semiconductor wafer 10 to be the n⁻-type drift region 1 may be prepared. The material of the semiconductor wafer 10 may be silicon (Si), diamond (C), or a compound semiconductor such as silicon carbide (SiC), gallium nitride (GaN), or digallium trioxide (Ga₂O₃). Hereinafter, a case where the semiconductor wafer 10 is a silicon wafer will be described as an example.

First, the front surface of the semiconductor wafer 10 is thermally oxidized to form a field oxide film covering the front surface of the semiconductor wafer 10, in the edge termination region. Next, a process including photolithography and ion implantation as one set is repeatedly performed under different conditions to form a surface device structure including a MOS structure in the semiconductor wafer 10, at the front surface thereof. For example, first, the p-type base region 2, the n⁺-type emitter regions 3, and the p⁺-type contact regions 4 of the IGBT are formed. The p-type base region 2 is formed in the entire active region from the IGBT region 21 to the FWD region 22. The p-type base region 2 also serves as a p-type anode region in the FWD region 22. The n⁺-type emitter regions 3 and the p⁺-type contact regions 4 are selectively formed inside the p-type base region 2 in the IGBT region 21. In addition, the p⁺-type well region 29 may be selectively formed in the edge termination region, at positions of the termination portion of the poly-runner 27 or the trenches 6, or the like.

A portion of the semiconductor wafer 10 other than the p-type base region 2, an n-type field stop (FS) layer 12 to be described later, the p⁺-type collector region 13, and the n⁺-type cathode region 14 is the n⁻-type drift region 1. In the IGBT region 21, the n-type accumulation layer 5 may be formed between the n⁻-type drift region 1 and the p-type base region 2. The n-type accumulation layer 5 serves as a barrier for minority carriers (holes) in the n⁻-type drift region 1 when the IGBT is turned on, and has a function of accumulating minority carriers in the n⁻-type drift region 1.

Next, by photolithography and etching, the trenches 6 are formed in the IGBT region 21 so as to penetrate the n⁺-type emitter regions 3, the p-type base region 2, and the n-type accumulation layer 5 and reach the n⁻-type drift region 1. When viewed from the front surface side of the semiconductor wafer 10, for example, the trenches 6 are arranged in a striped layout extending in a direction (longitudinal direction in FIG. 3) orthogonal to a direction (lateral direction in FIG. 3) in which the IGBT region 21 and the FWD region 22 are arranged.

The trenches 6 are also formed in the FWD region 22 in the same layout as the IGBT region 21. In the FWD region 22, the trenches 6 penetrate through the p-type base region 2 (p-type anode region) and reach the n⁻-type drift region 1. Next, the gate insulating films 7 are formed along the inner walls of the trenches 6 by, for example, thermal oxidation.

Next, a poly-silicon (poly-Si) film is formed at the front surface of the semiconductor wafer 10 so as to be embedded in the trenches 6. Next, the poly-silicon film is etched back, for example, to leave portions thereof to be the gate electrodes 8 in the trenches 6. The poly-runner 27 and the gate insulating films 7 thereunder may be left at the front surface of the semiconductor wafer 10 by photolithography and etching. After this etching, channel ion implantation may be performed in the p-type base region 2.

Next, the n⁺-type emitter regions 3, the p⁺-type contact regions 4, and the n-type accumulation layer 5 may be formed. The n⁺-type emitter regions 3 may be disposed in at least one mesa region between adjacent trenches 6 (mesa region), and there may be a mesa region that is free of the n⁺-type emitter regions 3. Further, the n⁺-type emitter regions 3 may be selectively disposed at predetermined intervals in the direction in which the trenches 6 extend in a striped pattern.

Next, after the surface device structure is formed, the interlayer insulating film 9 including two layers of, for example, a BPSG film and an HTO film is formed at the front surface of the semiconductor wafer 10 so as to cover the gate electrodes 8. Next, the interlayer insulating film 9 is patterned to form the contact holes 20 that penetrate through the interlayer insulating film 9 in a depth direction. The depth direction is a direction from the front surface to the back surface of the semiconductor wafer 10. The n⁺-type emitter regions 3 and the p⁺-type contact regions 4 are exposed in the contact holes 20 of the IGBT region 21. The p-type base region 2 is exposed in the contact holes 20 of the FWD region 22. A high-concentration p-type plug region may be formed in the exposed p⁺-type contact regions 4 and the outermost surface of the p-type base region 2 by further ion implantation.

Next, a Ti film 17 is uniformly formed in the contact holes 20 and on the surface of the interlayer insulating film 9 by sputtering. Next, a TiN film 18 is formed on the surface of the Ti film 17 by sputtering. Thus, the barrier metal 25 is stacked on the interlayer insulating film 9 and in the contact holes 20. Next, the Ti film 17 at the bottom of the contact holes 20 is converted to a silicide by a heat treatment (annealing) to form a titanium silicide film 55.

Next, the surface of the TiN film 18 and the inside of the contact holes 20 are filled with a contact plugs by, e.g., CVD. Next, the contact plugs outside the contact holes 20 are removed by etching to form the plug electrodes 15 in the contact holes 20. When the plug electrodes 15 are formed with the same composition as that of the front electrode 11 to be formed later, this step may be omitted.

Next, the barrier metal 25 on the interlayer insulating film 9 is patterned so as to be left only near the polyimide film 31 to be formed later. As a result, the barrier metal 25 remains on the interlayer insulating film 9 in the second region 42 and the first region 43, and does not remain on the interlayer insulating film 9 in the third region 41. At this time, in the third region 41, the interlayer insulating film 9 may also be partially etched. At this time, when the interlayer insulating film 9 also has regions where dopant ions for forming the plug regions are implanted, the region may be removed. The contact plugs may be left above the interlayer insulating film 9, and patterning may be performed simultaneously with or separately from the contact plugs and the barrier metal 25. When the contact plugs are not formed in the contact holes 20, the barrier metal 25 in the contact holes 20 may also be removed in the third region 41, and the silicide at the bottom of the contact holes 20 may or may not remain.

Next, an Al metal film serving as the front electrode 11 is formed by, for example, a sputtering method. The Al metal film may be formed of, for example, aluminum (Al—Si) containing silicon at a ratio of 1%. Next, the Al metal film is patterned. Next, the patterned Al metal film is annealed under a hydrogen atmosphere to form the front electrode 11.

The front electrode 11 is electrically connected to the p-type base region 2, the n⁺-type emitter regions 3, and the p⁺-type contact regions 4 in the IGBT region 21, and functions as an emitter electrode. The front electrode 11 is electrically connected to the p-type base region 2 in the FWD region 22 and functions as an anode electrode. The front electrode 11 may be electrically connected to the p-type base region 2 in a mesa region that is free of the n⁺-type emitter regions 3.

Next, the semiconductor wafer 10 is ground from the back surface side to a position of a product thickness used as a semiconductor device. Next, a process including photolithography and ion implantation as one set is repeatedly performed under different conditions to form a back surface device structure in the semiconductor wafer 10, at the back surface thereof. For example, the n-type field stop (FS) layer 12, the n⁺-type cathode region 14, and the p⁺-type collector region 13 are formed.

The p⁺-type collector region 13 is formed in the ground semiconductor wafer 10, at the entire back surface of the semiconductor wafer 10. The n-type field stop layer 12 is formed at a position deeper from the ground back surface of the semiconductor wafer 10 than is the p⁺-type collector region 13. The n-type field stop layer 12 is formed at least from the IGBT region 21 to the FWD region 22. The n-type field stop layer 12 may be in contact with the p⁺-type collector region 13.

Next, the n⁺-type cathode region 14 is formed by changing a portion of the p⁺-type collector region 13 corresponding to the FWD region 22 to an n⁺-type by photolithography and ion implantation. That is, the n⁺-type cathode region 14 is in contact with the p⁺-type collector region 13 in the direction in which the IGBT region 21 and the FWD region 22 are arranged. The n⁺-type cathode region 14 may be in contact with the n-type field stop layer 12 in the depth direction. Next, the p⁺-type collector region 13, the n⁺-type cathode region 14, and the n⁺-type field stop layer 12 are activated by a heat treatment (annealing). The annealing may be performed separately for each ion implantation.

Next, the polyimide film (passivation film) 31 is formed at the front surface of the semiconductor wafer 10. Next, the passivation film is patterned to expose the emitter electrode pad and each electrode pad. The polyimide film 31 may cover the edge termination region and the like. The polyimide film 31 is selectively left in a region where the barrier metal 25 remains on the interlayer insulating film 9 so as to retreat by a predetermined width from a boundary where the barrier metal 25 does not remain on the interlayer insulating film 9. Thus, the first region 43, the second region 42, and the third region 41 are formed. As the passivation film, a silicon nitride film or the like may be used instead of the polyimide film 31.

Next, a photoresist film (not depicted) having openings corresponding to the lifetime control region 26 is formed at the front surface of the semiconductor wafer 10. Using this photoresist film as a mask (shielding film), helium irradiation with high acceleration energy and a deep range may be performed to introduce (form) a lattice defect, serving as a lifetime killer, into the n⁻-type drift region 1, thereby forming the lifetime control region 26. In another example, the lifetime control may be performed on the entire surface of the wafer or a part of the wafer by performing helium irradiation with a high acceleration energy and a deep range from the back side of the semiconductor wafer 10, or the lifetime control may be performed on the entire surface of the wafer by a particle beam such as an electron beam that well penetrates the semiconductor wafer 10.

Then, the photoresist film is removed by an ashing treatment (ashing). The lifetime may be adjusted by performing annealing to partially recover defects in the lifetime control region 26. Next, the back electrode 24 is formed at the entire back surface of the semiconductor wafer 10. The back electrode 24 is in contact with the p⁺-type collector region 13 and the n⁺-type cathode region 14. The back electrode 24 functions as a collector electrode and also functions as a cathode electrode. Thereafter, the semiconductor wafer 10 is cut (diced) into individual chips, thereby completing the RC-IGBT 150 chips (semiconductor chips).

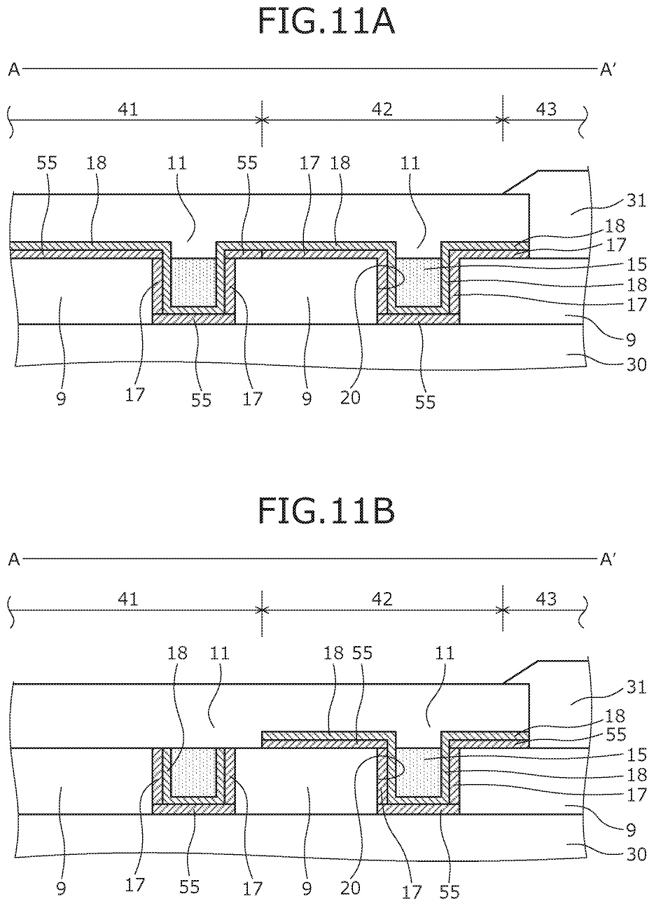

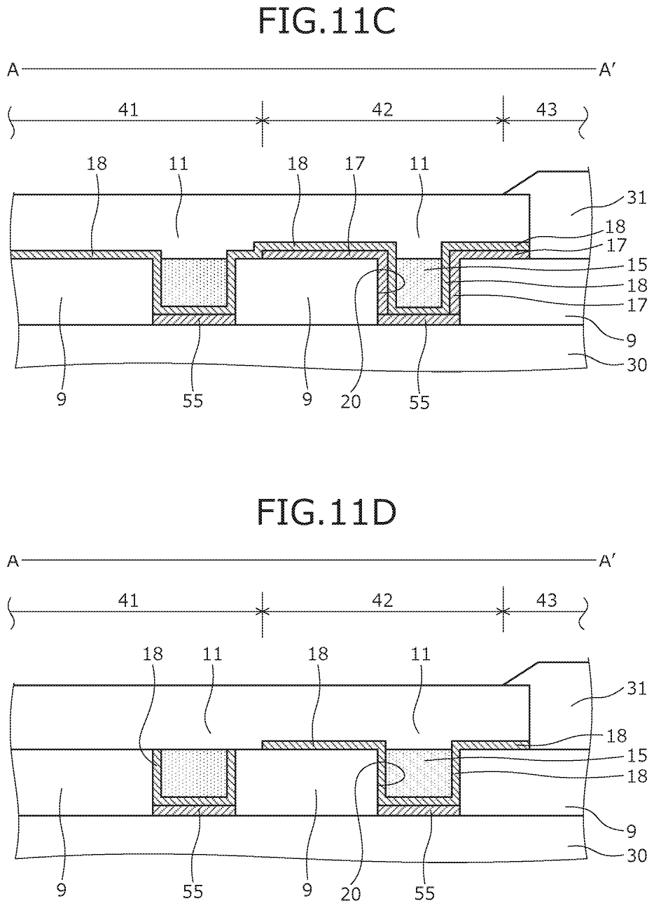

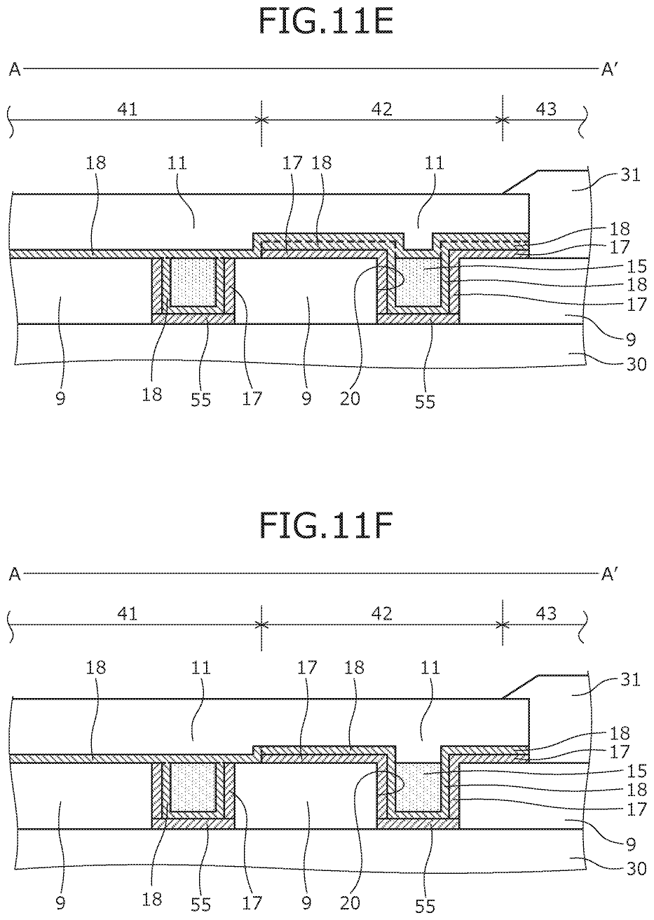

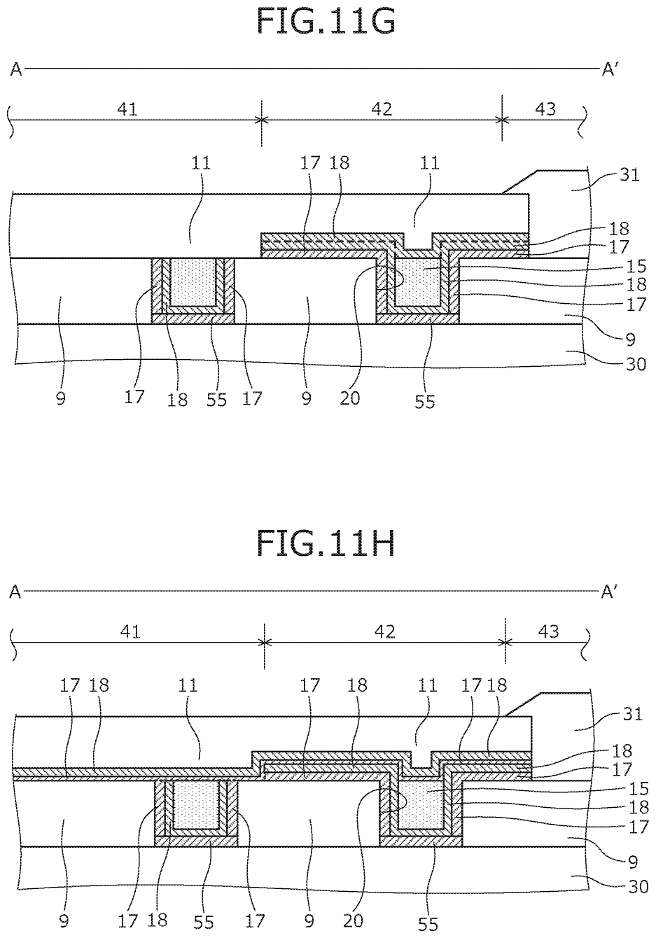

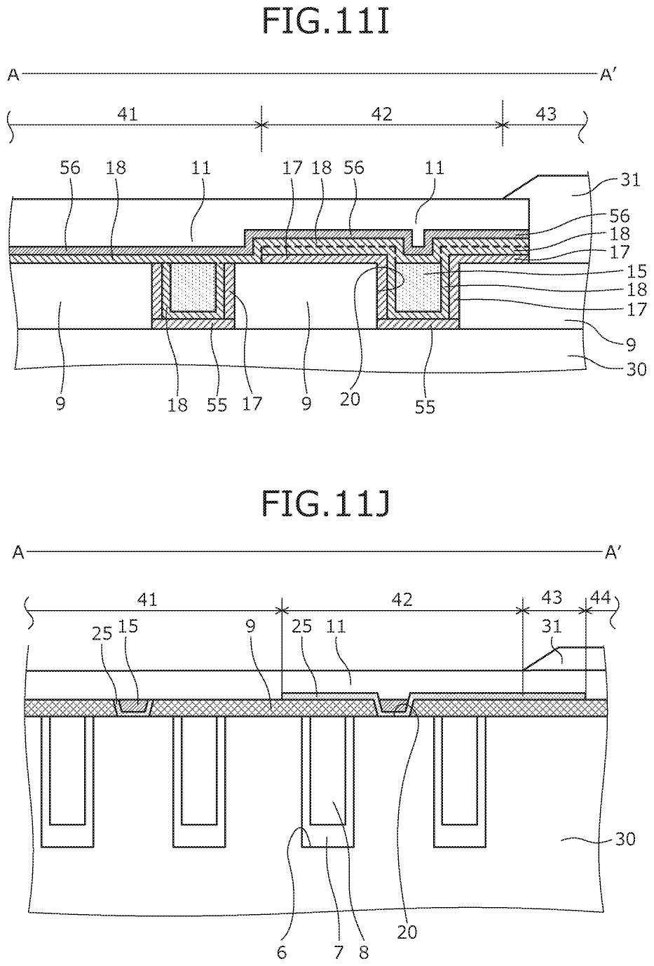

FIGS. 11A, 11B, 11C, 11D, 11E, 11F, 11G, 11H, 11I, and 11J are cross-sectional views of other structures of the semiconductor device according to the embodiment, along cutting line A-A′. In FIG. 11A, as an example of a method of reducing Ti in the exposed portion (third region 41) of the front electrode 11 away from the boundary of the polyimide film 31, the barrier metal 25 including the titanium silicide film 55 and the TiN film 18 is provided on the interlayer insulating film 9. Poly-silicon or a thin Ti film may be formed in contact with the titanium silicide film 55. An alloy film with another semiconductor material may be used, and in the case of using another metal other than Ti that occludes hydrogen, an alloy film of the other metal may be used. In the structure in FIG. 11A, the titanium silicide film 55 is formed by reacting the Ti film 17 with poly-silicon or the like on the surface of the interlayer insulating film 9. In this case, since the amount of Ti simple substance in the barrier metal 25 remaining on the interlayer insulating film 9 is small, occlusion of hydrogen by Ti is reduced, and a decrease in threshold voltage is reduced. The Ti film 17 may be formed at the side wall of the contact holes 20 in the third region 41. In another example, instead of the Ti film 17, the titanium silicide film 55 may be provided at the side wall of the contact holes 20 in the third region 41.

The structure depicted in FIG. 11A may be fabricated as follows. Hereinafter, differences from the manufacturing method of the structure in FIG. 2 described above will be described, and description of the same processes will be omitted. First, the interlayer insulating film 9 is formed. Next, poly-silicon is deposited. Next, the poly-silicon is patterned to remove the poly-silicon in the second region 42 and the first region 43. Next, the contact holes 20 are formed. Next, dopant ions may be implanted into the bottom of the contact holes 20, and annealing may be performed to form a high-concentration p-type plug region. Next, a Ti film 17 and a TiN film 18 are formed by sputtering and annealed. In the third region 41, since poly-silicon is also present on the interlayer insulating film 9, the Ti film 17 reacts with Si to form a titanium silicide film 55. The unreacted poly-silicon or Ti film 17 may be left. Next, contact plugs are formed in the contact holes 20 and on the TiN film 18 on the interlayer insulating film 9. Next, the contact plugs on the interlayer insulating film 9 are removed, and the plug electrodes 15 are formed in the contact holes 20. Next, the front electrode 11 is formed. Alternatively, after the interlayer insulating film 9 is formed, the contact holes 20 may be formed and then poly-silicon may be deposited and patterned to remove the poly-silicon in the second region 42 and the first region 43. In this case, in the third region 41, since poly-silicon is also present at the side wall of the contact holes 20, the titanium silicide film 55 is formed at the side wall of the contact holes 20.

When the titanium silicide film 55 and the TiN film 18 on the interlayer insulating film 9 are removed in the third region 41 from the structure in FIG. 11A, the same structure as that in FIG. 2 is obtained. When the titanium silicide film 55 is formed without the Ti film 17 at the side wall of the contact holes 20 in the third region 41, Ti may be further reduced in the third region 41.

In FIG. 11B, as an example of a method of eliminating Ti in the exposed portion (third region 41) of the front electrode 11 apart from the boundary of the polyimide film 31, the barrier metal 25 formed of the titanium silicide film 55 and the TiN film 18 is provided in the second region 42 without providing the barrier metal 25 on the interlayer insulating film 9 in the third region 41. That is, the configuration of the second region 42 of the structure in FIG. 11B is similar to the configuration of the third region 41 of the structure in FIG. 11A. Also in this case, since the amount of Ti simple substance in the barrier metal 25 left on the interlayer insulating film 9 is small (or disappears), occlusion of hydrogen by Ti is reduced, and a decrease in threshold voltage is reduced.

The structure in FIG. 11B may be fabricated as follows. First, the interlayer insulating film 9 is formed. Next, poly-silicon is deposited. Next, the contact holes 20 are formed. Next, dopant ions may be implanted into the bottom of the contact holes 20, and annealing may be performed to form high-concentration p-type plug regions. Next, the Ti film 17 and the TiN film 18 are formed by sputtering and annealed. The Ti film 17 reacts with Si to form a titanium silicide film 55. Next, contact plugs are formed in the contact holes 20 and on the TiN film 18 on the interlayer insulating film 9. Next, the contact plugs on the interlayer insulating film 9 is removed, and the plug electrodes 15 is formed in the contact holes 20. Next, the titanium silicide film 55 and the TiN film 18 are patterned, and the titanium silicide film 55 and the TiN film 18 in the third region 41 are removed by etching. Next, the front electrode 11 is formed. The deposition of poly-silicon may be performed after the formation of the contact holes 20 as described in the method of manufacturing the structure in FIG. 11A.

By forming the barrier metal 25 composed of the titanium silicide film 55 and the TiN film 18 on the interlayer insulating film 9 in the second region 42 and removing the Ti film 17 and the TiN film 18 on the interlayer insulating film 9 in the third region 41, the same structure may be formed excluding the structure in the contact holes 20 in the third region 41. Even when only the TiN film 18 on the interlayer insulating film 9 is removed in the third region 41 to leave the titanium silicide film 55, the amount of Ti simple substance in the barrier metal 25 remaining on the interlayer insulating film 9 is small (or disappears). Therefore, the amount of hydrogen occlusion by Ti is small, and the decrease in threshold voltage is reduced. At this time, in the third region 41, an oxide film or the like may be formed on the surface of the titanium silicide film 55 on the interlayer insulating film 9 along with the removal of the TiN film 18.

In FIG. 11C, as an example of a method of reducing Ti in the exposed portion (third region 41) of the front electrode 11 apart from the boundary of the polyimide film 31, a barrier metal 25 containing only the TiN film 18 is provided on the interlayer insulating film 9. At the sidewalls of the contact holes 20 in the third region 41, the Ti film 17 is not provided, and only the TiN film 18 is provided. In the structure in FIG. 11C, after the Ti film 17 is reacted with silicon at the bottom of the contact holes 20 to form the titanium silicide film 55, the Ti film 17 is removed in the third region 41, and then the TiN film 18 is formed. Also in this case, since the amount of Ti simple substance in the barrier metal 25 remaining on the interlayer insulating film 9 is small, occlusion of hydrogen by Ti is reduced, and a decrease in threshold voltage is reduced. In the third region 41, an oxide film or the like may be formed on the surface of the titanium silicide film 55 at the bottom of the contact holes 20 as the Ti film 17 is removed.

The structure in FIG. 11C may be fabricated as follows. First, the interlayer insulating film 9 is formed. Next, the contact holes 20 are formed. Next, dopant ions may be implanted into the bottom of the contact holes 20, and annealing may be performed to form the high-concentration p-type plug regions. Next, the Ti film 17 is formed by a sputtering method, and annealing is performed. Next, the Ti film 17 is patterned, and in the third region 41, the Ti film 17 on the interlayer insulating film 9 and in the contact holes 20 is removed by etching while leaving the titanium silicide film 55 at the bottom of the contact holes 20. Next, the TiN film 18 is formed by sputtering. Next, the contact plugs are formed in the contact holes 20 and on the TiN film 18 on the interlayer insulating film 9. Next, the contact plugs on the interlayer insulating film 9 are removed, and the plug electrodes 15 are formed in the contact holes 20. Next, the front electrode 11 is formed.

When the TiN film 18 on the interlayer insulating film 9 is removed from the structure in the third region 41 in FIG. 11C, the structure is the same as that in FIG. 2 except that the Ti film 17 is not present at the sidewalls of the contact holes 20 in the third region 41. When it is desired to reduce Ti in the third region 41 as much as possible, such a structure may be adopted.

FIG. 11D depicts an example of a method of eliminating Ti in the exposed portion (third region 41) of the front electrode 11 apart from the boundary of the polyimide film 31. In this example, the barrier metal 25 is not provided in the third region 41, and the barrier metal 25 containing the TiN film 18 is provided in the second region 42. That is, the configuration of the second region 42 of the structure in FIG. 11D is similar to the configuration of the third region 41 of the structure in FIG. 11C. Also in this case, since the amount of Ti simple substance in the barrier metal 25 remaining on the interlayer insulating film 9 is small (or disappears), the occlusion of hydrogen by Ti is reduced (or eliminated), and a decrease in threshold voltage is reduced.

The structure in FIG. 11D may be fabricated as follows. First, the interlayer insulating film 9 is formed. Next, the contact holes 20 are formed. Next, dopant ions may be implanted at the bottoms of the contact holes 20, and annealing may be performed to form the high-concentration p-type plug regions. Next, the Ti film 17 is formed by a sputtering method, and annealing is performed. Next, the Ti film 17 on the interlayer insulating film 9 and in the contact holes 20 is removed by etching while leaving the titanium silicide film 55 at the bottoms of the contact holes 20. Next, the TiN film 18 is formed by sputtering. Next, the contact plugs are formed in the contact holes 20 and on the TiN film 18 on the interlayer insulating film 9. Next, the contact plugs on the interlayer insulating film 9 are removed, and the plug electrodes 15 are formed in the contact holes 20. Next, the TiN film 18 is patterned, and the TiN film 18 in the third region 41 is removed by etching. Next, the front electrode 11 is formed.

In the second region 42, the Ti film 17 is removed and the TiN film 18 is formed on the interlayer insulating film 9. In the third region 41, the Ti film 17 and the TiN film 18 on the interlayer insulating film 9 are removed.

FIG. 11E depicts an example of a method in which the barrier metal 25 formed only of the TiN film 18 is provided on the interlayer insulating film 9, thereby reducing Ti in the exposed portion (third region 41) of the front electrode 11 apart from the boundary of the polyimide film 31. Also in this case, since the amount of Ti simple substance in the barrier metal 25 remaining on the interlayer insulating film 9 is small, occlusion of hydrogen by Ti is reduced, and a decrease in threshold voltage is reduced. In the structure in FIG. 11E, after the Ti film 17 and the TiN film 18 are formed on the interlayer insulating film 9, the Ti film 17 and the TiN film 18 are removed in the third region 41, and the TiN film 18 is formed again. The TiN film 18 may or may not be formed on the plug electrodes 15. In the second region 42, the barrier metal 25 composed of the Ti film 17 and the thick TiN film 18 is provided on the interlayer insulating film 9. The structure in FIG. 11E is one of effective structures in a case where it is desired to provide a certain amount of barrier metal 25 in order to prevent diffusion of the front electrode 11 into the semiconductor wafer 10 also into the third region 41 when the barrier metal 25 is formed in preparation for a defect of the front electrode 11 in the second region 42. Also in FIGS. 11A and 11C, the TiN film 18 is provided in the third region 41, so that the same effect is obtained.

The structure in FIG. 11E may be fabricated as follows. First, the interlayer insulating film 9 is formed. Next, the contact holes 20 are formed. Next, dopant ions may be implanted at the bottoms of the contact holes 20, and annealing may be performed to form the high-concentration p-type plug regions. Next, the Ti film 17 and the TiN film 18 are formed by sputtering and annealed. Next, the contact plugs are formed in the contact holes 20 and on the TiN film 18 on the interlayer insulating film 9. Next, the contact plugs on the interlayer insulating film 9 are removed, and the plug electrodes 15 are formed in the contact holes 20. Next, the Ti film 17 and the TiN film 18 are patterned, and the TiN film 18 on the interlayer insulating film 9 is removed in the third region 41 by etching. Next, the TiN film 18 is formed by sputtering. Next, the front electrode 11 is formed. The TiN film 18 on the plug electrodes 15 may be removed before forming the front electrode 11.

In FIG. 11F, the TiN film 18 that is formed again in the second region 42 is removed from the structure in FIG. 11E. In the second region 42, when the Ti film 17 and the TiN film 18 formed before the formation of the plug electrodes 15 provide sufficient ion shielding performance, the TiN film 18 formed again may be removed to further reduce hydrogen occlusion. The TiN film 18 may or may not be formed on the plug electrodes 15 in the third region 41. The TiN film 18 on the plug electrodes 15 in the third region 41 may be removed when the TiN film 18 on the interlayer insulating film 9 in the second region 42 is etched. On the other hand, in FIG. 11G, the TiN film 18 formed again in the third region 41 is removed from the structure in FIG. 11E. In the third region 41, the barrier metal 25 is not necessary on the interlayer insulating film 9. However, when it is desired to form a thick barrier metal 25 in the second region 42, the TiN film 18 formed again may be left only in the second region 42 to reduce hydrogen occlusion. The TiN film 18 may or may not be formed on the plug electrodes 15 in the second region 42. The TiN film 18 on the plug electrodes 15 in the second region 42 may be removed simultaneously with the TiN film 18 on the interlayer insulating film 9 in the third region 41.

In FIG. 11H, in the exposed portion (third region 41) of the front electrode 11 away from the boundary of the polyimide film 31, the barrier metal 25 formed of the thin Ti film 17 and TiN film 18 is provided on the interlayer insulating film 9. In this example, as in the example depicted in FIG. 11E, the Ti film 17 and the TiN film 18 may or may not be formed on the plug electrodes 15. In the second region 42, the barrier metal 25 in which the Ti film 17, the TiN film 18, the Ti film 17, and the TiN film 18 are stacked in this order is provided on the interlayer insulating film 9. For example, the thickness of the thin Ti film 17 on the interlayer insulating film 9 in the third region 41 is preferably 50% or less of the thickness of the lowermost Ti film 17 on the interlayer insulating film 9 in the second region 42. For example, the thickness of the Ti film 17 on the interlayer insulating film 9 in the third region 41 is preferably 20 nm or less. Also in this case, since the amount of Ti simple substance in the barrier metal 25 remaining on the interlayer insulating film 9 is small, occlusion of hydrogen by Ti is reduced, and a decrease in threshold voltage is reduced. Since the structure in FIG. 11H includes the Ti film 17, the ion shielding performance may be enhanced as compared with the structure in FIG. 11E in which only the TiN film 18 is formed again. Before the Ti film 17 is formed again, the TiN film 18 may be formed, that is, TiN/Ti/TiN may be formed in this order.

The structure in FIG. 11H may be fabricated as follows. First, the interlayer insulating film 9 is formed. Next, the contact holes 20 are formed. Next, dopant ions may be implanted at the bottoms of the contact holes 20, and annealing may be performed to form the high-concentration p-type plug regions. Next, the Ti film 17 and the TiN film 18 are formed by sputtering and annealed. Next, contact plugs are formed in the contact holes 20 and on the TiN film 18 on the interlayer insulating film 9. Next, the contact plugs on the interlayer insulating film 9 are removed, and the plug electrodes 15 are formed in the contact holes 20. Next, the Ti film 17 and the TiN film 18 are patterned, and in the third region 41, the Ti film 17 and the TiN film 18 on the interlayer insulating film 9 are removed by etching. Then, the thin Ti film 17 and the thin TiN film 18 are formed by sputtering. Next, the front electrode 11 is formed. The Ti film 17 and the TiN film 18 on the plug electrodes 15 may be removed before forming the front electrode 11.

The Ti film 17 and the TiN film 18 formed again in the second region 42 may be removed from the structure in FIG. 11H. That is, the thin Ti film 17 and the TiN film 18 may be formed instead of the TiN film 18 formed again in FIG. 11F. In the second region 42, when the Ti film 17 and the TiN film 18 formed before the formation of the plug electrodes 15 provide sufficient ion shielding performance, the thin Ti film 17 and TiN film 18 formed again may be removed to further reduce hydrogen occlusion. On the other hand, the Ti film 17 and the TiN film 18 formed again in the third region 41 may be removed from the structure in FIG. 11H. That is, the Ti film 17 and the TiN film 18 may be formed instead of the TiN film 18 formed again in FIG. 11G. In the third region 41, the barrier metal 25 is not necessary on the interlayer insulating film 9. However, when it is desired to form a thick barrier metal 25 in the second region 42, the Ti film 17 and the TiN film 18 formed again may be left only in the second region 42 to reduce hydrogen occlusion. When the thickness of the Ti film 17 formed before the formation of the plug electrodes 15 is increased, a defect may occur at the bottom of the contact holes 20. This defect may be avoided by forming the Ti film 17 after the formation of the plug electrodes 15. In this case, the thickness of the Ti film 17 newly formed after the formation of the plug electrodes 15 may be larger than the thickness of the Ti film 17 formed before the formation of the plug electrodes 15.

In FIG. 11I, in the exposed portion (third region 41) of the front electrode 11 away from the boundary of the polyimide film 31, as an example of a method of reducing Ti, the barrier metal 25 including the TiN film 18 and a tungsten film 56 is provided on the interlayer insulating film 9. In this example, as in the example depicted in FIG. 11E, the TiN film 18 and the tungsten film 56 may or may not be formed on the plug electrodes 15. As another example, a metal such as Ta or Ni may be used, or a nitride thereof may be used. Since the structure in FIG. 11I includes the tungsten film 56, the ion shielding performance may be enhanced as compared with the structure in FIG. 11E in which only the TiN film 18 is formed again. Alternatively, only the tungsten film 56 may be formed without forming the TiN film 18 to reduce hydrogen occlusion. Also in this case, since the amount of Ti simple substance in the barrier metal 25 remaining on the interlayer insulating film 9 is small, occlusion of hydrogen by Ti is reduced, and a decrease in threshold voltage is reduced.

The structure in FIG. 11I may be fabricated as follows. First, the interlayer insulating film 9 is formed. Next, the contact holes 20 are formed. Next, dopant ions may be implanted at the bottoms of the contact holes 20, and annealing may be performed to form the high-concentration p-type plug regions. Next, the Ti film 17 and the TiN film 18 are formed by sputtering and annealed. Next, the contact plugs are formed in the contact holes 20 and on the TiN film 18 on the interlayer insulating film 9. Next, the contact plugs on the interlayer insulating film 9 are removed, and the plug electrodes 15 are formed in the contact holes 20. Next, in the third region 41, the Ti film 17 and the TiN film 18 on the interlayer insulating film 9 are removed by etching, and the TiN film 18 and the tungsten film 56 are formed by sputtering. Next, the front electrode 11 is formed. The TiN film 18 and the tungsten film 56 on the plug electrodes 15 may be removed before forming the front electrode 11.

The TiN film 18 and the tungsten film 56 formed in the second region 42 may be removed from the structure in FIG. 11I. That is, the TiN film 18 and the tungsten film 56 may be formed instead of the TiN film 18 formed again in FIG. 11F. In the second region 42, when the Ti film 17 and the TiN film 18 formed before the formation of the plug electrodes 15 may provide sufficient ion shielding performance, the formed TiN film 18 and the tungsten film 56 may be removed to further reduce hydrogen occlusion. On the other hand, the TiN film 18 and the tungsten film 56 formed in the third region 41 may be removed from the structure in FIG. 11I. That is, instead of the TiN film 18 formed again in FIG. 11G, the TiN film 18 and the tungsten film 56 may be formed. Although the barrier metal 25 is not necessary on the interlayer insulating film 9 in the third region 41, when it is desired to form the thick barrier metal 25 in the second region 42, the TiN film 18 and the tungsten film 56 formed only in the second region 42 may be left to reduce hydrogen occlusion.

In FIG. 11J, in the fourth region 44 apart from the boundary of the polyimide film 31 below the polyimide film 31, that is, in the fourth region 44 below the polyimide film 31 and not adjacent to the second region 42, the barrier metal 25 is not provided on the surface of the interlayer insulating film 9 covered by the front electrode 11, similarly to the exposed portion (third region 41) of the front electrode 11 apart from the boundary of the polyimide film 31. In this case as well, since the amount of the Ti simple substance (Ti film) in the barrier metal 25 remaining on the interlayer insulating film 9 is small or disappears, hydrogen occlusion by Ti is reduced, and the decrease in the threshold voltage is reduced. An example of the method of reducing Ti in the third region 41 and the fourth region 44 may be the example of the method of reducing or eliminating the Ti film 17 in the third region 41 described with reference to FIGS. 2 and 11A to 11I.

Further, the structure in FIG. 11J may be fabricated by not forming the Ti film 17 also in the fourth region 44 similarly to the third region 41 or forming the Ti film 17 thinner than the first region 43 and the second region 42 in the above-described manufacturing method.

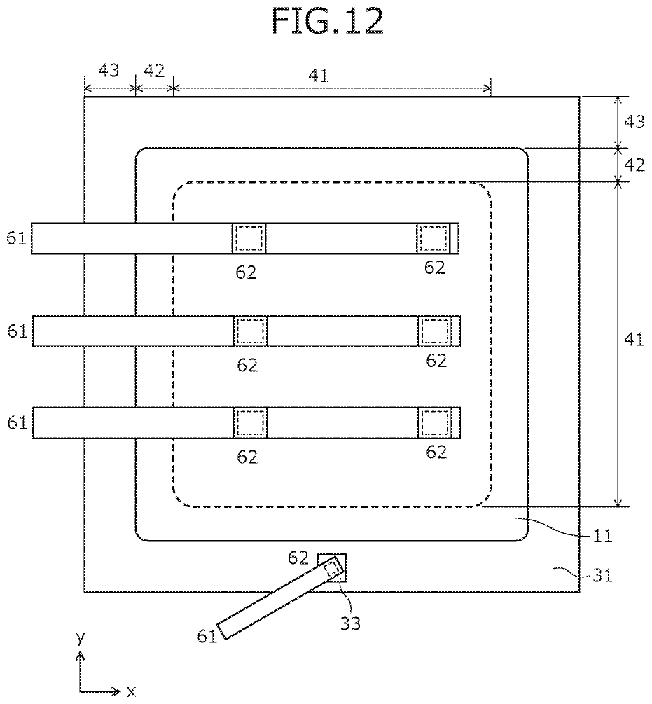

FIG. 12 is a top view when the semiconductor device according to the embodiment is mounted. As depicted in FIG. 12, in the present example, a region (hereinafter, referred to as a bonded region) in which a connection portion 62 to which a wiring portion 61 is connected is provided in the emitter electrode pad is provided in the third region 41 and is not provided in the second region 42. The connection portion 62 may be a part of the wiring portion 61. The wiring portion 61 may be ultrasonically bonded to the upper surface of the front electrode 11 at the connection portion 62. In FIG. 12, as in FIG. 4, the second region 42 is annularly provided in the opening of one emitter electrode pad, and one third region 41 is provided inside the second region 42. However, the present disclosure is not limited hereto, and for example, even in the semiconductor device having the arrangement depicted in FIG. 10, the region to be bonded may be provided in the third region 41 instead of being provided in the second region 42.

In the second region 42, the Ti film 17 is present between the front electrode 11 and the interlayer insulating film 9, but the adhesion between the Ti film 17 and the interlayer insulating film 9 is not good. Therefore, when bonding is performed on the second region 42, the Ti film 17 may peel off due to an impact caused by wiring, and the front electrode 11 may peel off. In another example, in the second region 42, there is a portion where the dopant ions for forming the plug region are also implanted into the interlayer insulating film 9, whereby the adhesion between the barrier metal 25 and the interlayer insulating film 9 is not good. Therefore, when bonding is performed on the second region 42, the barrier metal 25 may peel off due to an impact caused by the wiring, and the front electrode 11 may peel off. In addition, even when the front electrode 11 is not peeled off, when the defect 34 is generated in a state where the barrier metal 25 is peeled off, the threshold voltage is lowered.

Since the front electrode 11 is directly formed on the interlayer insulating film 9 in the third region 41, the adhesion between the front electrode 11 and the interlayer insulating film 9 is enhanced as compared with the case where the front electrode 11 is formed via the Ti film 17, and peeling of the front electrode 11 due to an impact associated with wiring does not occur. In another example, since the TiN film 18 is formed on the interlayer insulating film 9 without the Ti film 17 in the third region 41, the adhesion between the TiN film 18 and the interlayer insulating film 9 is enhanced as compared with the case where the TiN film 18 is formed via the Ti film 17, and the peeling of the barrier metal 25 and the front electrode 11 due to the impact associated with the wiring does not occur. In another example, in the third region 41, a process of removing the barrier metal on the interlayer insulating film 9 is performed, and a portion where the implantation of the dopant ions for forming the plug regions is also performed on the interlayer insulating film 9 is removed at that time, so that the adhesion between the barrier metal 25 or the front electrode 11 and the interlayer insulating film 9 is increased as compared with the case where the front electrode 11 is formed via the Ti film 17 formed before the plug electrodes 15 is formed, and the peeling of the barrier metal 25 or the front electrode 11 due to an impact associated with the wiring does not occur.

As described above, since the region to be bonded is provided in the third region 41 and is not provided in the second region 42, peeling of the barrier metal 25 and the front electrode 11 and a decrease in threshold due to an impact associated with wiring do not occur.

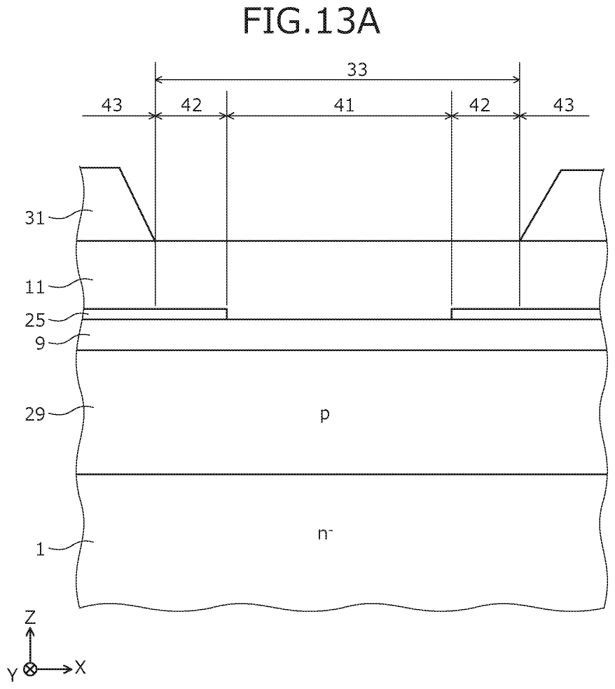

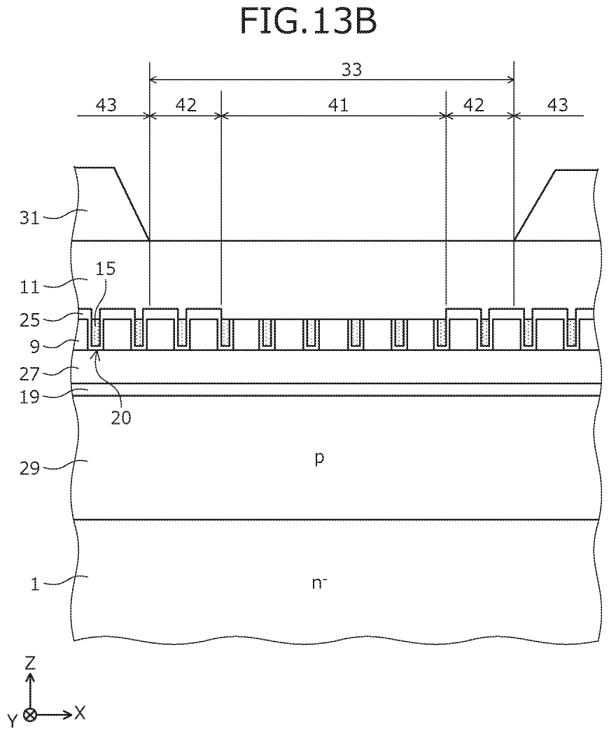

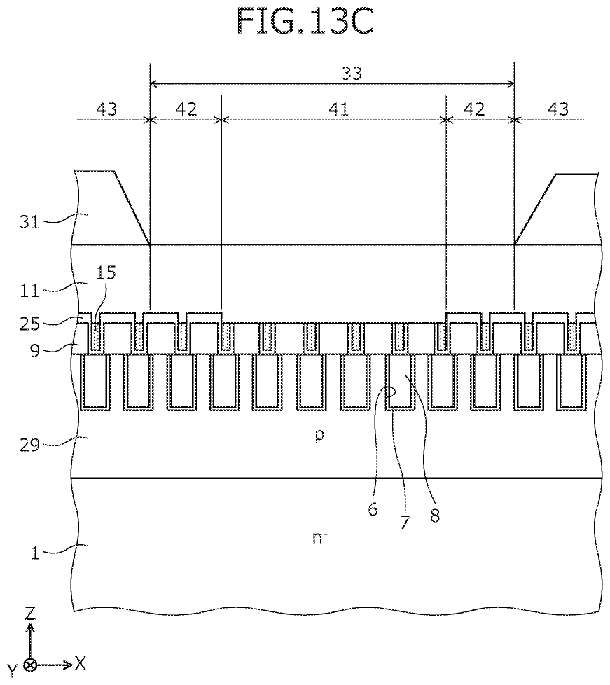

FIGS. 13A, 13B, and 13C are cross-sectional views depicting a structure in a vicinity of the gate electrode pad 33 of the semiconductor device according to the embodiment. FIGS. 13A to 13C depict a structure in a vicinity of a pad other than a front electrode pad (for example, the emitter electrode pad or the source electrode pad) through which a main current flows. The same structure may be used when a pad other than the gate electrode pad, for example, a pad of a temperature sensing/protection diode portion wiring is provided.

FIG. 13A depicts a structure in the vicinity of the gate electrode pad 33. The contact holes 20 are not provided in the interlayer insulating film 9 under the gate electrode pad 33 of the present example, and the semiconductor wafer 10 and the front electrode 11 are not connected to each other. The front electrode 11 in the present example may be a gate finger. Also in the gate electrode pad 33, the barrier metal 25 may be provided between the interlayer insulating film 9 and the front electrode 11 in the second region 42, close to the polyimide film 31, and the barrier metal 25 may be omitted between the interlayer insulating film 9 and the front electrode 11 in the third region 41 away from the boundary of the polyimide film 31. As described above, hydrogen occlusion by the barrier metal 25 may be reduced to suppress a decrease in the threshold voltage.

FIG. 13B depicts another structure in the vicinity of the gate electrode pad 33. Under the gate electrode pad 33 of the present example, the contact holes 20 are provided in the interlayer insulating film 9, and the front electrode 11 is connected to the poly-runner 27 containing poly-silicon (polycrystalline portion) and provided on the semiconductor wafer 10 via the insulating film 19. The insulating film 19 and the poly-runner 27 may be formed simultaneously with or separately from the gate insulating films 7 and the gate electrodes 8. Also in the gate electrode pad 33 of the present example, the barrier metal 25 may be provided between the interlayer insulating film 9 and the front electrode 11 in the second region 42 close to the polyimide film 31, and the barrier metal 25 may be omitted between the interlayer insulating film 9 and the front electrode 11 in the third region 41 away from the boundary of the polyimide film 31. As described above, hydrogen occlusion by the barrier metal 25 may be reduced to suppress the decrease in the threshold voltage.

FIG. 13C depicts another structure in the vicinity of the gate electrode pad 33. Under the gate electrode pad 33 of the present example, the contact holes 20 are provided in the interlayer insulating film 9, and the front electrode 11 is connected to the gate electrodes 8 containing poly-silicon (polycrystalline portion) and provided in the trenches 6 provided in the semiconductor wafer 10 via the gate insulating films 7. The trenches 6 may or may not extend to the active region. Also in the gate electrode pad 33 of the present example, the barrier metal 25 may be provided between the interlayer insulating film 9 and the front electrode 11 in the second region 42 close to the polyimide film 31, and the barrier metal 25 may be omitted between the interlayer insulating film 9 and the front electrode 11 in the third region 41 away from the boundary of the polyimide film 31. As described above, hydrogen occlusion by the barrier metal 25 may be reduced to suppress the decrease in the threshold voltage.

Although the examples depicted in FIGS. 13A to 13C are described as examples of a structure similar to the structure in the vicinity of the active region depicted in FIG. 2, a structure similar to the structure described with reference to FIGS. 11A to 11J may also be applied to the vicinity of the gate electrode pad 33.

The examples depicted in FIGS. 13A to 13C may be fabricated in the same manner as the method of manufacturing the structure in the vicinity of the active region depicted in FIGS. 2 and 11A to 11J.

Also in the gate electrode pad 33, a region to be bonded at the time of mounting may be provided not in the second region 42 but in the third region 41. As a result, in the vicinity of the connection portion 62, adhesion between the front electrode 11 or the barrier metal 25 and the interlayer insulating film 9 is improved, and peeling of the front electrode 11 or the barrier metal 25 is prevented.

As described above, according to the embodiment, the barrier metal, which occludes hydrogen, is eliminated on the entire surface between the interlayer insulating film and the front electrode of the semiconductor device, but is left only near the polyimide film or is left in a small amount in a region away from the polyimide film. As a result, since the amount of Ti in the barrier metal remaining on the interlayer insulating film is small, hydrogen occlusion by Ti is reduced, and a decrease in threshold voltage is reduced. Therefore, the semiconductor device may be manufactured with desirable characteristics and yield.

In the foregoing, in the present disclosure, while a case where a MOS gate structure is formed in the silicon substrate, at the first main surface thereof has been described as an example, the present disclosure is not limited hereto and the type of semiconductor (for example, silicon carbide (SiC) or the like), the plane orientation of the substrate main surface, and the like may be variously changed. In addition, in the embodiments of the present disclosure, while a trench IGBT has been described as an example, the present disclosure is not limited hereto and is applicable to semiconductor devices having various configurations such as a MOS semiconductor device such as a trench MOSFET. Further, in the present disclosure, in each of the embodiments, while the first conductivity type is assumed to be an n-type and the second conductivity type is assumed to be a p-type, the present disclosure is similarly implemented when the first conductivity type is a p-type and the second conductivity type is an n-type.

According to the above disclosure, the barrier metal is not left on the entire surface of the semiconductor device, but is left only near the polyimide film. As a result, since the amount of Ti in the barrier metal remaining on the interlayer insulating film is small, hydrogen occlusion by Ti is reduced, and a decrease in threshold voltage is reduced. Therefore, the semiconductor device may be manufactured with desirable characteristics and yield.

According to the semiconductor device of the present disclosure, it is possible to suppress a decrease in the threshold voltage while leaving the barrier metal on the interlayer insulating film.

As described above, the semiconductor device according to the present disclosure is useful for high-voltage semiconductor devices used in a power converting equipment, power supply devices of various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate having a first semiconductor layer of a first conductivity type;
a gate insulating film having a first surface and a second surface opposite to each other, the second surface thereof being in contact with the first semiconductor layer;
a gate electrode provided on the first surface of the gate insulating film;
an interlayer insulating film provided on said gate electrode;
a contact hole penetrating through the interlayer insulating film to reach a surface of the first semiconductor layer;
a front electrode selectively formed on a surface of the interlayer insulating film and in the contact hole;
a sealing film selectively formed on surfaces of the front electrode and the interlayer insulating film, to thereby define, in a top view of the semiconductor device,
a first region that is a region in which the sealing film is formed,
a second region that is a region in which the sealing film is not formed, and
a third region that is another region in which the sealing film is not formed,
the second region being adjacent to the first region, the third region being adjacent to the second region but not adjacent to the first region; and
a first barrier metal containing a first metal, the first barrier metal being sandwiched between the front electrode and the interlayer insulating film in the second region but not in the third region.

2. The semiconductor device according to claim 1, further comprising a second barrier metal having a smaller hydrogen storage capacity than that of the first barrier metal between the front electrode and the interlayer insulating film in the third region.

3. The semiconductor device according to claim 2, wherein the second barrier metal is free of the first metal or contains less of the first metal than does the first barrier metal.

4. The semiconductor device according to claim 3, wherein the second barrier metal is a compound film of the first metal.

5. The semiconductor device according to claim 4, wherein the compound film of the first metal is a nitride film.

6. The semiconductor device according to claim 4, wherein the compound film of the first metal includes a compound film with a semiconductor material.

7. The semiconductor device according to claim 3, wherein
the first barrier metal includes a single film of the first metal.

8. The semiconductor device according to claim 3, wherein the second barrier metal includes a second metal different from the first metal or a compound film of the second metal.

9. The semiconductor device according to claim 1, wherein the first metal is titanium.

10. The semiconductor device according to claim 1, further comprising:
a second semiconductor layer of a second conductivity type, provided on a surface of the first semiconductor layer; and
a transistor region further including a second semiconductor region of the first conductivity type, selectively provided in the second semiconductor layer, at the surface thereof.

11. The semiconductor device according to claim 10, wherein the transistor region is provided in the third region but not in the second region.

12. The semiconductor device according to claim 10, further comprising a lifetime control region.

13. The semiconductor device according to claim 12, wherein the transistor region in the second region is free of the lifetime control region.

14. The semiconductor device according to claim 13, further comprising a diode region.

15. The semiconductor device according to claim 14, further comprising in the second region, a non-operating region between the diode region and the transistor region free of the lifetime control region.

16. The semiconductor device according to claim 14, wherein
the diode region is provided in the third region, but not in the second region.

17. The semiconductor device according to claim 14, wherein
the diode region is provided in the second region, but not in the third region.

18. The semiconductor device according to claim 10, further comprising a diode region.

19. The semiconductor device according to claim 1, wherein the first barrier metal is further provided between the front electrode and the interlayer insulating film in the first region.

20. The semiconductor device according to claim 19, wherein
the semiconductor device further has, in the top view, a fourth region in contact with the first region and apart from the second region,
the sealing film is formed in the fourth region, and
the front electrode and the interlayer insulating film in the fourth region are free of the first barrier metal therebetween.
